(19) United States
(12) Patent Application Publication
(10) Pub. No.: US 2004/0201096 A1
(43) Pub. Date: Oct. 14, 2004

(54) Wiring circuit board, manufacturing method for the wiring circuit board, and circuit module

(76) Inventors: Tomoo Iijima, Tokyo (JP); Kimitaka Endo, Tokyo (JP); Kazuo Ikenaga, Tokyo (JP); Hiroshi Odaira, Tokyo (JP); Naoto Minari, Tokyo (JP); Takashi Kato, Tokyo (JP)

Correspondence Address: ARMSTRONG, KRATZ, QUINTOS, HANSON & BROOKS, LLP, 1725 K STREET, NW, SUITE 1000, WASHINGTON, DC, 20006, US

(21) Appl. No.: 10/812,349

(22) Filed: Mar. 30, 2004

(30) Foreign Application Priority Data
Mar. 31, 2003 (JP) 2003-95167
Apr. 23, 2003 (JP) 2003-118182
Jul. 4, 2003 (JP) 2003-192192
Aug. 7, 2003 (JP) 2003-289319
Aug. 29, 2003 (JP) 2003-307897

(51) Int. Cl. H01L 23/48

(52) U.S. Cl. 257/734

(57) ABSTRACT

An object of the present invention is to reduce the number of steps necessary for connecting between a wiring circuit board and a printed circuit board and to achieve a low-cost wiring circuit board. A wiring circuit board (2) includes an insulating film (4), a bump (6), an etching barrier layer (8), and a wiring layer (10). The bump (6) is made of copper and formed to penetrate through the insulating film (4). A top face of the bump (6) is exposed at a surface of the insulating film (4) flush therewith. The etching barrier layer (8) is made of nickel (Ni) and formed underneath the bump (6). The bump (6) is connected to the wiring layer (10) through the etching barrier layer (8). A solder ball (12) is formed on the top face of the bump (6). A printed circuit board (14) as a rigid board is connected to the wiring circuit board (2). A wiring layer (16) is connected to the bump (6) through the solder ball (12) to thereby mount the wiring circuit board (2) to the printed circuit board (14).

### BACKGROUND OF THE INVENTION

1. Field of the Invention

The present invention relates to a wiring circuit board for packaging an electronic device such as an IC or an LSI. In particular, the present invention relates to a wiring circuit board capable of high-density packaging, a manufacturing method for the wiring circuit board, and a circuit module including the wiring circuit board.

2. Description of the Related Art

In recent years, a semiconductor manufacturing technique has made a significant progress. A dramatic progress in fine pattern forming technique such as a mask processing technique or an etching technique realizes miniaturization of a semiconductor device. Here, in order to realize high integration of a wiring board, it is necessary to form a multilayer wiring circuit board as well as finely establish connection between an upper wiring film and a lower wiring film with a high reliability.

The applicants of the present invention have studied about a manufacturing method for a multilayer wiring circuit board and developed a wiring circuit board in which a metal film made of a copper foil etc. is etched from one surface side through wet etching to form a bump having a substantially trapezoidal shape in vertical section as an interlayer connection means. The applicants have also developed a technique of manufacturing the multilayer wiring circuit board by appropriately processing the wiring circuit board.

In a conventional technique, a method of connecting between the bump of the wiring circuit board and a wiring layer of another printed circuit board through a solder ball is as illustrated in FIGS. 13A to 13I. Referring now to FIGS. 13A to 13I, description is given of a manufacturing process for the wiring circuit board and the method of connecting between the wiring circuit board and the other printed circuit board in the conventional technique. FIGS. 13A to 13I are sectional views of a wiring circuit board, each of which illustrates a manufacturing method therefor in the manufacturing step order in the conventional technique.

As shown in FIG. 13A, a multilayer metal plate 20 is prepared. The multilayer metal plate 20 includes: a wiring layer forming metal layer 20c formed of a copper foil with a thickness of about 12 to 30 μm; an etching barrier layer 20b formed of nickel (Ni) with a thickness of about 0.5 to 2.0 μm and laminated on the layer 20c; and a bump forming metal layer 20a formed of a copper foil having a thickness of about 80 to 150 μm and laminated on the layer 20b.

Next, a resist is applied onto the bump forming metal layer 20a, followed by exposure using an exposure mask with plural circular patterns and then development. As shown in FIG. 13B, a resist mask 5 is thus formed.

Subsequently, as shown in FIG. 13C, the bump forming metal layer 20a is patterned through etching by using the resist mask 5 as a mask. As a result, a bump 6 is formed in a conical (konide) shape as a means for establishing continuity between an upper wiring layer and a lower wiring layer.

The shape of the bump 6 is described in more detail. The resist mask 5 has the circular pattern and therefore the bump 6 is circular in cross-section. Now that wet etching is adopted in etching, the bump forming metal layer 20a is subjected to isotropic etching. Therefore, an etchant infiltrates into a portion beneath the resist mask 5, so that etching proceeds in a lateral direction as well as a vertical direction (side etching). As a result, the bump 6 takes a substantially trapezoidal shape in vertical section. At the time of etching the bump forming metal layer 20a, the etching barrier layer 20b prevents the wiring layer forming metal layer 20c from being etched.

As shown in FIG. 13D, the resist mask 5 is peeled off. After that, as shown in FIG. 13E, the etching barrier layer 20b is etched using the bump 6 as a mask and removed. At this point, the etching barrier layer 20b is interposed between the bump 6 and the wiring layer forming metal layer 20c.

Next, as shown in FIG. 13F, an insulating film 4 constituted of a resin film sheet, for example, is squeezed from above the bump 6. After that, the insulating film 4 formed on the bump 6 is selectively etched to form an opening 12a. Alternatively, the insulating film 4 formed on the bump 6 is irradiated with a laser beam to form the opening 12a.

Following this, a metal layer of a multilayer structure made of copper, nickel, gold, etc., is formed on the insulating film 4 by plating. The metal layer is selectively etched. As a result, as shown in FIG. 13G, a solder ball base film 12b is formed over the opening 12a. In addition, as shown in FIG. 13H, the wiring layer forming metal layer 20c is selectively etched to thereby form a wiring layer 10. Subsequently, a solder ball 12 is formed on the solder ball base film 12b.

Each electrode of a semiconductor chip (not shown) such as an LSI is connected to each wiring layer 10. The semiconductor chip is mounted on the wiring circuit board.

As shown in FIG. 13I, the wiring circuit board is mounted to a printed circuit board 14. More specifically, each wiring layer 16 of the printed circuit board 14 is connected to the solder ball 12 and hence, the wiring circuit board is mounted to the printed circuit board 14.

The conventional technique requires a large number of steps in the manufacturing process from the formation of the insulating film 4 on the wiring circuit board until the formation of the solder ball 12, resulting in an increase in production cost. In the conventional technique, a considerably large number of steps are necessary as mentioned below. That is, after being formed, the insulating film 4 is selectively etched to form the opening 12a. Next, the multilayer solder ball base film 12b is formed by plating, followed by selective etching for patterning in such a way as to separately define the solder ball base film 12b connected to each bump 6. Then, the solder ball 12 is formed.

### SUMMARY OF THE INVENTION

The present invention has been made to solve the above-mentioned problem and has an object to realize a low-cost wiring circuit board by omitting a step of connecting a wiring circuit board and another printed circuit board with a bump of the wiring circuit board used as an interlayer connection means.

A conventional technique has a problem in that a solid film sheet made of a resin, for example, is used for an insulating film 4, so that an adhesion between a bump 6 and the resin of the insulating film is insufficient unless otherwise modified. To cope therewith, the insulating film 4 needs to be heat-pressed and laminated thereon. Accordingly, an additional heat-pressing apparatus is necessary. The film should be heat-pressed for a long time. The wiring circuit board involves a low productivity.

Meanwhile, there is a method of forming the wiring layer on a top face of the bump 6 by laminating another wiring layer forming metal layer on the insulating film 4 without interposing the solder ball 12 therebetween. In this method, the wiring layer forming metal layer is laminated on the insulating film 4 and pressurized to flatten out the bump 6, thereby press-bonding onto the insulating film 4. The bump 6 is thus connected to the wiring layer forming metal layer. The wiring layer forming metal layer is etched and patterned to form another wiring layer on the top face of the bump 6.

In such a method, for example, in the case of forming a wiring circuit board where a thickness of the insulating film 4 (height of the bump 6) is about 50 μm after press-bonding, the wiring layer forming metal layer press-bonds to the insulating film while flattening out the bump 6. Thus, it is necessary to previously form the bump 6 having a height of about 100 μm, for example. Assuming that the bump 6 having a height of 100 μm, for example, is formed by wet etching, however, a distance between the adjacent bumps 6 should be set to about 300 to 350 μm in consideration of an influence of side etching. As a result, a fine pattern cannot be formed, making it impossible to manufacture a highly integrated wiring circuit board nor a highly integrated multilayer wiring circuit board utilizing the wiring circuit board.

The present invention has been also made to solve the above problem and has another object to provide a manufacturing method for a wiring circuit board capable of omitting a heat-pressing step upon forming an insulating film by using a liquid insulating material and capable of attaining a high productivity. Another object of the present invention is to provide a manufacturing method for a highly integrated wiring circuit board, which does not require a step of press-bonding a wiring layer forming metal layer to flatten out a bump upon forming a wiring layer on a top face of the bump, thereby eliminating the need to form the bump higher than necessary. Another object of the present invention is to provide a highly integrated multilayer wiring circuit board that is achieved by laminating the wiring circuit board of the present invention.

According to a first aspect of the present invention, there is provided a wiring circuit board including: a plurality of bumps each formed on a surface of a wiring layer directly or indirectly through an etching barrier layer; an insulating film formed on the surface of the wiring layer on which the bumps are formed at a portion in which the bumps are not formed; and a solder ball formed on a top face of each of the bumps directly or indirectly through an additional wiring layer.

Note that it is not always necessary to form the etching barrier layer between the wiring layer and the bump. This is because the bump can be formed in such a way that the bump forming metal layer is half-etched selectively from one surface (etched into a thickness smaller than that of the metal layer as appropriate). In such a case, the etching barrier layer may be omitted. The same is applied to a wiring circuit board according to another aspect of the present invention.

According to a second aspect of the present invention, in the wiring circuit board according to the first aspect of the invention, the wiring layer, an additional wiring layer, and the bumps are made of copper.

According to a third aspect of the present invention, in the wiring circuit board according to the first or second aspect of the invention, the insulating film has a bump formation region where the plurality of bumps are formed and a flexible bump non-formation region where the bumps are not formed; and the bump non-formation region can be bent or at least a part of the bump non-formation region is bent.

According to a fourth aspect of the present invention, in the wiring circuit board according to any one of the first to third aspects of the invention, the top face of each of the bumps is formed in a rounded concave shape; and the solder ball is directly formed on the top face of each of the bumps.

According to a fifth aspect of the present invention, there is provided a circuit module, including: a flexible wiring circuit board including: a plurality of bumps each formed on a surface of a wiring layer directly or indirectly through an etching barrier layer; an insulating film formed on the surface of the wiring layer on which the bumps are formed at a portion in which the bumps are not formed; and a solder ball formed on a top face of each of the bumps directly or indirectly through an additional wiring layer; and a rigid wiring circuit board having a rigid insulated board where a wiring layer is formed on at least one surface thereof, which is connected to the wiring layer, in which at least a part of the wiring layer of the flexible wiring circuit board and at least a part of the wiring layer of the rigid wiring circuit board are connected to each other through the solder ball.

According to a sixth aspect of the present invention, there is provided a circuit module including: a flexible wiring circuit board including: a plurality of bumps each formed on a surface of a wiring layer directly or indirectly through an etching barrier layer; an insulating film formed on the surface of the wiring layer on which the bumps are formed at a portion in which the bumps are not formed; and a solder ball formed on a top face of each of the bumps directly or indirectly through an additional wiring layer; and an additional flexible wiring circuit board having a flexible insulated board having at least one surface on which a wiring layer connected to the wiring layer is formed, in which at least a part of the wiring layer of the flexible wiring circuit board and at least a part of the wiring layer of the additional flexible wiring circuit board are connected to each other through the solder ball.

According to a seventh aspect of the present invention, in the circuit module according to the fifth or sixth aspect of the invention, the top face of each of the bumps is formed in a rounded concave shape; and the solder ball is directly formed on the top face of each of the bumps.

According to an eighth aspect of the present invention, there is provided a manufacturing method for a wiring circuit board including: forming a board in which a bump is formed on a surface of a metal layer directly or indirectly through an etching barrier layer; forming an insulating film on the surface of the metal layer on which the bump is formed at a portion in which the bump is not formed while making the insulating film thicker than the bump; polishing the insulating film to an extent to which a top face of the bump is exposed; and forming a solder ball on the top face of the bump.

According to a ninth aspect of the present invention, there is provided a manufacturing method for a wiring circuit board including: forming a board in which a bump is formed on a surface of a metal layer directly or indirectly through an etching barrier layer; forming an insulating film on the surface of the metal layer on which the bump is formed at a portion in which the bump is not formed while making the insulating film thicker than the bump; polishing the insulating film of the board to an extent to which a top face of the bump is exposed; forming an additional metal layer on the surface of the insulating film of the board; selectively etching the additional metal layer to form a wiring layer; and forming a solder ball on the top face of the bump directly or indirectly through the wiring layer connected to the bump.

According to a tenth aspect of the present invention, in the manufacturing method for a wiring circuit board according to the eighth or ninth aspect of the invention, further including, before forming the insulating film, pressurizing the bump from above and flattening out the bump to thereby increase a diameter of the top face of the bump.

According to an eleventh aspect of the present invention, in the manufacturing method for a wiring circuit board according to any one of the eighth to tenth aspects of the invention, further including, after polishing the insulating film to an extent to which the top face of the bump is exposed and before forming the solder ball on the top face of the bump, etching the top face of the bump into a rounded concave shape.

According to a twelfth aspect of the present invention, there is provided a circuit module including: a single wiring circuit board including: a plurality of bumps each formed on a surface of a wiring layer directly or indirectly through an etching barrier layer; and an insulating film formed on the surface of the wiring layer on which the bumps are formed at a portion in which the bumps are not formed; and a transparent board for a liquid crystal device which constitutes a board for the liquid crystal device and includes a transparent wiring film, in which each of the bumps of the single wiring circuit board and a portion corresponding to the bump, of the transparent wiring film of the transparent board for the liquid crystal device are connected to each other directly or indirectly through the wiring layer formed on the top face of the bump and a solder ball thereon.

According to a thirteenth aspect of the present invention, in the circuit module according to the twelfth aspect of the invention, the top face of the bump of the signal wiring circuit board is formed in a rounded concave shape; and the solder ball is directly formed on the top face of the bump.

According to a fourteenth aspect of the present invention, there is provided a manufacturing method for a wiring circuit board in which a bump is formed on a surface of a metal layer directly or indirectly through an etching barrier layer, including: forming an insulating film by applying a liquid insulating material on the surface of the metal layer on which the bump is formed and solidifying the insulating material through heat treatment; and removing the insulating film of the board to an extent to which a top face of the bump is exposed.

According to a fifteenth aspect of the present invention, there is provided a manufacturing method for a wiring circuit board using a multilayer metal plate in which a bump forming metal layer is formed on a wiring layer forming metal layer directly or indirectly through an etching barrier layer, including: forming a bump by applying a resist onto the bump forming metal layer and forming a resist mask through patterning, and etching the bump forming metal layer by using the resist mask as a mask; removing the etching barrier layer through etching by using the bump as a mask after removing the resist mask; forming an insulating film by applying a liquid insulating material on the surface of the metal layer on which the bump is formed and solidifying the insulating material through heat treatment; and removing the insulating film of the board to an extent to which a top face of the bump is exposed.

According to a sixteenth aspect of the present invention, in the manufacturing method for a wiring circuit board according to the fourteenth or fifteenth aspect of the invention, the insulating material is made of a precursor of a polyimide resin or an epoxy resin.

According to a seventeenth aspect of the present invention, in the manufacturing method for a wiring circuit board according to the fourteenth or fifteenth aspect of the invention, in forming the insulating film, an insulating material made of a melted thermoplastic resin is applied on the surface of the board on which the bump is formed and solidified under cooling to form the insulating film.

According to an eighteenth aspect of the present invention, in the manufacturing method for a wiring circuit board according to the fourteenth or fifteenth aspect of the invention, in forming the insulating film, the liquid insulating material is applied onto the surface of the board on which the bump is formed, left standing to dry and solidify, leveled by a roller, and cured through heat treatment to form the insulating film.

According to a nineteenth aspect of the present invention, in the manufacturing method for a wiring circuit board according to the fourteenth or fifteenth aspect of the invention, in forming the insulating film, a thermoplastic polyimide resin is applied onto the surface of the board on which the bump is formed and dried and solidified under heating, applied with a non-thermoplastic polyimide resin in a precursor form, and dried and solidified under heating to form the insulating film.

According to a twentieth aspect of the present invention, in the manufacturing method for a wiring circuit board according to any one of the fourteenth to nineteenth aspects of the invention, in removing the insulating film, the insulating film is mechanically polished to an extent to which at least the top face of the bump is exposed.

According to a twenty-first aspect of the present invention, in the manufacturing method for a wiring circuit board according to any one of the fourteenth to nineteenth aspects of the invention, in removing the insulating film, a resist is applied onto the insulating film and the resist on the bump is removed through exposure and development, and the insulating film formed on the bump is removed through etching by using as a mask the resist applied onto a portion where the bump is not formed to an extent to which at least the top face of the bump is exposed.

According to a twenty-second aspect of the present invention, in the manufacturing method for a wiring circuit board according to any one of the fourteenth to nineteenth aspects of the invention, in removing the insulating film, the insulating film is wholly etched and removed to an extent to which at least the top face of the bump is exposed.

According to a twenty-third aspect of the present invention, in the manufacturing method for a wiring circuit board according to any one of the fourteenth to nineteenth aspects of the invention, in removing the insulating film, the insulating film formed on the bump is removed by laser processing to an extent to which at least the top face of the bump is exposed.

According to a twenty-fourth aspect of the present invention, in the manufacturing method for a wiring circuit board according to any one of the fourteenth to nineteenth aspects of the invention, in removing the insulating film, the insulating film is removed by injecting a gas containing an abrasive onto the surface of the insulating film to an extent to which at least the top face of the bump is exposed.

According to a twenty-fifth aspect of the present invention, in the manufacturing method for a wiring circuit board according to any one of the fourteenth to nineteenth aspects of the invention, in removing the insulating film, the insulating film is removed by injecting a liquid containing an abrasive onto the surface of the insulating film to an extent to which at least the top face of the bump is exposed.

According to a twenty-sixth aspect of the present invention, in the manufacturing method for a wiring circuit board according to anyone of the fourteenth to twenty-fifth aspects of the invention, in forming the insulating film, the insulating film is formed with a thickness larger than a height of the bump.

According to a twenty-seventh aspect of the present invention, in the manufacturing method for a wiring circuit board according to any one of the fourteenth to twenty-fifth aspects of the invention, in forming the insulating film, the insulating film is formed with a thickness smaller than a height of the bump.

According to a twenty-eighth aspect of the present invention, there is provided a manufacturing method for a wiring circuit board using a board having a wiring layer forming metal layer and a bump formed on the wiring layer forming metal layer directly or indirectly through an etching barrier layer, including: applying a material repelling a liquid resin onto a top face of the bump; applying a liquid insulating material there onto; and solidifying the insulating material through heat treatment to thereby form an insulating film.

According to a twenty-ninth aspect of the present invention, in the manufacturing method for a wiring circuit board according to any one of the fourteenth to twenty-eighth aspects of the invention, the method further includes, after removing the insulating film, forming a protrusion made of metal on the top face of the bump by plating.

According to a thirtieth aspect of the present invention, in the manufacturing method for a wiring circuit board according to the twenty-ninth aspect of the invention, the method further includes, after forming the protrusion by plating, forming a wiring layer by partially etching the wiring layer forming metal layer.

According to a thirty-first aspect of the present invention, in the manufacturing method for a wiring circuit board according to any one of the fourteenth to twenty-eighth aspects of the invention, the method further includes, after removing the insulating film, forming a wiring layer by partially etching the wiring layer forming metal layer.

According to a thirty-second aspect of the present invention, in the manufacturing method for a wiring circuit board according to the thirty-first aspect of the invention, the method further includes, after forming the wiring layer, forming a protrusion made of metal on the top face of the bump by plating.

According to a thirty-third aspect of the present invention, in the manufacturing method for a wiring circuit board according to any one of the fourteenth to twenty-eighth aspects of the invention, the method further includes, after removing the insulating film: laminating an additional wiring layer forming metal layer on the insulating film; and forming a wiring layer by partially etching the additional wiring layer forming metal layer.

According to a thirty-fourth aspect of the present invention, in the manufacturing method for a wiring circuit board according to anyone of the fourteenth to twenty-eighth aspects of the invention, the method further includes, after removing the insulating film, wholly removing the wiring layer forming metal layer through etching.

According to a thirty-fifth aspect of the present invention, in the manufacturing method for a wiring circuit board according to anyone of the fourteenth to twenty-eighth aspects of the invention, the method further includes, after removing the insulating film: partially forming a first metal film on the insulating film; forming a resistor film on the insulating film at a portion where the first metal film is not formed; forming a dielectric film on the first metal film; forming a second metal film on the dielectric film; and forming a wiring layer by partially etching the wiring layer forming metal layer formed on the wiring circuit board.

According to a thirty-sixth aspect of the present invention, in the manufacturing method for a wiring circuit board according to the thirty-fifth aspect of the invention, the first metal film and the second metal film are made of a conductive paste, the resistor film is made of a resistor paste, and the dielectric film is made of a dielectric paste.

According to a thirty-seventh aspect of the present invention, in the manufacturing method for a wiring circuit board according to the thirty-fifth aspect of the invention, the first metal film, the second metal film, the resistor film, and the dielectric film are formed by one selected from the group consisting of a sputtering method, a CVD method, and an evaporation method.

According to a thirty-eighth aspect of the present invention, in the manufacturing method for a wiring circuit board according to any one of the fourteenth to twenty-eighth aspects of the invention, the method further includes, after removing the insulating film: forming a wiring layer by partially etching the wiring layer forming metal layer to connect a part of the wiring layer with the bump directly or indirectly through the etching barrier layer; and forming an electromagnetic shielding sheet wholly or partially on a surface in which the top face of the bump is exposed.

According to a thirty-ninth aspect of the present invention, there is provided a manufacturing method for a wiring circuit board using a wiring circuit board manufactured by the manufacturing method for the wiring circuit board according to any one of the fourteenth to twenty-eighth aspects of the invention, including: forming a thin film made of metal on the insulating film and the top face of the bump by electroless plating or sputtering; forming a metal film on the thin film by electrolytic plating; and forming a wiring layer by applying a resist onto the metal film to form a resist pattern through patterning, and etching the metal film using the resist pattern as a mask.

According to a fortieth aspect of the present invention, there is provided a manufacturing method for a wiring circuit board using a wiring circuit board manufactured by the manufacturing method for the wiring circuit board according to any one of the fourteenth to twenty-eighth aspects of the invention, including: forming a thin film made of metal on the insulating film and the top face of the bump by electroless plating or sputtering; forming a resist pattern by applying a resist onto the thin film and performing patterning; precipitating metal by plating onto the thin film on which the resist pattern is not formed; and removing the thin film by removing the resist pattern and wholly etching the film.

According to a forty-first aspect of the present invention, there is provided a manufacturing method for a wiring circuit board using a wiring circuit board manufactured by the manufacturing method for the wiring circuit board according to any one of the fourteenth to twenty-eighth aspects of the invention, including: forming a through-hole by removing a part of the insulating film on the wiring circuit board by laser processing or etching; forming a thin film on the insulating film and the top face of the bump by electroless plating or sputtering; forming a metal film on the thin film by electrolytic plating; and forming a wiring film by applying a resist onto the metal film to form a resist pattern through patterning, and etching the metal film using the resist pattern as a mask.

According to a forty-second aspect of the present invention, there is provided a manufacturing method for a wiring circuit board using a wiring circuit board manufactured by the manufacturing method for the wiring circuit board according to any one of the fourteenth to twenty-eighth aspects of the invention, including: forming a through-hole by removing a part of the insulating film on the wiring circuit board by laser processing or etching; forming a thin film on the insulating film and the top face of the bump by electroless plating or sputtering; forming a resist pattern by applying a resist onto the thin film and performing patterning; precipitating metal by plating onto the thin film on which the resist pattern is not formed; and removing the thin film by removing the resist pattern and wholly etching the film.

According to a forty-third aspect of the present invention, there is provided a manufacturing method for a multilayer wiring circuit board using a wiring circuit board manufactured by the manufacturing method for the wiring circuit board according to the thirty-third aspect of the invention, including: forming a multilayer metal plate by laminating a wiring circuit board manufactured by the manufacturing method for the wiring circuit board according to the twenty-ninth aspect of the invention, which has a protrusion formed on the top face of the bump directly or indirectly through a bonding sheet such that the protrusion comes into contact with the wiring layer; and forming wiring layers on both of upper and lower surfaces of the multilayer metal plate by partially etching wiring layer forming metal layers formed on both of the upper and lower surfaces.

According to a forty-fourth aspect of the present invention, there is provided a manufacturing method for a multilayer wiring circuit board using a wiring circuit board manufactured by the manufacturing method for the wiring circuit board according to the thirty-third aspect of the invention, including: forming a multilayer metal plate by laminating a wiring circuit board manufactured by the manufacturing method for the wiring circuit board according to the twenty-seventh aspect of the invention, in which a bump is formed such that a top face of the bump comes into contact with the wiring layer directly or indirectly through a bonding sheet; and forming wiring layers on both of upper and lower surfaces of the multilayer metal plate by partially etching the wiring layer forming metal layers formed on both of the upper and lower surfaces.

According to a forty-fifth aspect of the present invention, there is provided a manufacturing method for a multilayer wiring circuit board using a wiring circuit board manufactured by the manufacturing method for the wiring circuit board according to the thirty-fifth aspect of the invention, including, with respect to both of upper and lower surfaces thereof, on which wiring layers are formed: forming a multilayer metal plate by laminating a wiring circuit board manufactured by the manufacturing method for the wiring circuit board according to the twenty-ninth aspect of the invention, which has a protrusion formed on a top face of a bump such that the protrusion comes into contact with the wiring layer; and forming wiring layers on both of upper and lower surfaces of the multilayer metal plate by partially etching the wiring layer forming metal layers formed on both of the upper and lower surfaces.

According to a forty-sixth aspect of the present invention, there is provided a manufacturing method for a multilayer wiring circuit board using a wiring circuit board manufactured by the manufacturing method for the wiring circuit board according to the thirty-fifth aspect of the invention, including, with respect to both of upper and lower surfaces thereof, on which wiring layers are formed: forming a multilayer metal plate by laminating a wiring circuit board manufactured by the manufacturing method for the wiring circuit board according to the twenty-seventh aspect of the invention, in which a bump is formed such that a top face of the bump comes into contact with the wiring layer; and forming wiring layers on both of upper and lower surfaces of the multilayer metal plate by partially etching the wiring layer forming metal layers formed on both of the upper and lower surfaces.

According to a forty-seventh aspect of the present invention, there is provided a manufacturing method for a multilayer wiring circuit board, including laminating on a wiring circuit board manufactured by the manufacturing method for the wiring circuit board according to the thirty-first aspect of the invention, in which a wiring layer is formed, an additional wiring circuit board manufactured by the manufacturing method for the wiring circuit board according to any one of the fourteenth to twenty-eighth aspects of the invention, in which a bump is formed such that a top face of the bump comes into contact with the wiring layer.

According to a forty-eighth aspect of the present invention, there is provided a manufacturing method for a multilayer wiring circuit board, including laminating on a wiring circuit board manufactured by the manufacturing method for the wiring circuit board according to the thirty-first aspect of the invention, an additional wiring circuit board manufactured by the manufacturing method for the wiring circuit board according to the thirty-first aspect of the invention, such that a top face of a bump of the additional wiring circuit board comes into contact with a wiring layer of the wiring circuit board.

According to a forty-ninth aspect of the present invention, there is provided a manufacturing method for a multilayer wiring circuit board, including laminating on a multilayer wiring circuit board manufactured by the manufacturing method for the multilayer wiring circuit board according to the forty-eighth aspect of the invention, a wiring circuit board manufactured by the manufacturing method for the wiring circuit board according to the thirty-fourth aspect of the invention, in which a bump is formed such that a bottom face of the bump comes into contact with a wiring layer of the multilayer wiring circuit board.

According to a fiftieth aspect of the present invention, there is provided a manufacturing method for a multilayer wiring circuit board using a wiring circuit board manufactured by the manufacturing method for the wiring circuit board according to the thirty-first aspect of the invention, including; forming an insulating film by applying a liquid insulating material onto a surface where the wiring layer is formed and solidifying the insulating material through heat treatment; forming a through-hole by removing a part of the insulating film by laser processing or etching; forming a thin film on the insulating film by electroless plating or sputtering; forming a metal film on the thin film by electrolytic plating; and forming a wiring film by applying a resist onto the metal film to form a resist pattern through patterning, and etching the metal film using the resist pattern as a mask.

According to a fifty-first aspect of the present invention, there is provided a manufacturing method for a multilayer wiring circuit board using a wiring circuit board manufactured by the manufacturing method for the wiring circuit board according to the thirty-first aspect of the invention, including; forming an insulating film by applying a liquid insulating material onto a surface where the wiring layer is formed and solidifying the insulating material through heat treatment; forming a through-hole by removing a part of the insulating film by laser processing or etching; forming a thin film on the insulating film by electroless plating or sputtering; forming a resist pattern by applying a resist onto the thin film and performing patterning; precipitating metal by plating onto the thin film on which the resist pattern is not formed; and removing the thin film by removing the resist pattern and wholly etching the film.

According to the first aspect of the present invention, the solder ball is formed on the top face of the bump directly or indirectly through the wiring layer, making it possible to save the trouble of forming a solder ball base film serving as a base for the solder ball. Consequently, the number of steps necessary for manufacturing the wiring circuit board can be reduced, enabling cost reduction in the wiring circuit board.

According to the second aspect of the present invention, the wiring layer and the bump are made of copper with a small resistivity, whereby a parasitic resistance can be diminished.

According to the third aspect of the prevent invention, the bump formation region where a number of bumps are formed and the bump non-formation region where no bump is formed are formed in the insulating film, and the bump non-formation region is partially bent when in use. Consequently, semiconductor chips such as an LSI can be stereoscopically arranged in use. As a result, a number of chips can be packaged in a limited space at a high integration scale.

According to the fourth aspect of the present invention, the top face of the bump is formed in a rounded concave shape and the solder ball is directly formed on the top face of the bump, whereby a connection area can be further widened, and a connection strength can be further increased. Consequently, a reliability of the wiring circuit board can be enhanced and a service life thereof can be prolonged.

According to the fifth aspect of the present invention, the flexible wiring circuit board is connected to the rigid wiring circuit board, whereby the flexible wiring circuit board can be used to lead out the electrode.

According to the sixth aspect of the present invention, the flexible wiring circuit board is connected to another flexible wiring circuit board, whereby the circuit module in which the flexible wiring circuit boards are integrated together can be provided.

According to the seventh aspect of the present invention, the top face of the bump is formed in the rounded concave shape and the solder ball is directly formed on the top face, whereby the connection area can be further widened and the connection strength can be further increased. Accordingly, the reliability of the circuit module can be enhanced and the service life thereof can be prolonged.

According to the eighth aspect of the present invention, the solder ball is formed on the top face of the bump directly or indirectly through the wiring layer, making it possible to save the trouble of forming the solder ball base film serving as the base for the solder ball. As a result, the number of steps necessary for manufacturing the wiring circuit board can be reduced, enabling cost reduction in the wiring circuit board.

According to the ninth aspect of the present invention, the wiring circuit board in which the wiring layers are formed on both surfaces of the insulating film can be manufactured.

According to the tenth aspect of the present invention, each bump is flattened out while pressurized from above prior to the formation of the insulating film, whereby the diameter of the top face of the bump can be increased. Consequently, the connection strength between the solder ball and each bump can be readily increased to a satisfactory level.

According to the eleventh aspect of the present invention, the top face of the bump is etched into the rounded concave shape prior to the formation of the solder ball on the top face of the bump, whereby the connection area between the solder ball and the top face can be widened, and the connection strength therebetween can be further increased. Thus, the reliability of the wiring circuit board can be further enhanced and the service life thereof can be prolonged.

According to the twelfth aspect of the present invention, the transparent wiring film of the liquid crystal device can be led out through the wiring circuit board according to the present invention.

According to the thirteenth aspect of the present invention, the top face of the bump is formed in the rounded concave shape and the solder ball is directly formed on the top face of the bump, whereby the connection area between the bump and the solder ball can be further widened and the connection strength can be further increased. Accordingly, the reliability of the circuit module can be enhanced and the service life thereof can be prolonged.

According to the fourteenth to thirty-eighth aspects of the present invention, the wiring circuit board is manufactured using the liquid insulating material, making it possible to dispense with the heat-pressing step and to improve the productivity of the wiring circuit board. In addition, there is no need to flatten out the bump to thereby enable the formation of the low bump. Consequently, the highly integrated wiring circuit board can be achieved.

Further, according to the twenty-first aspect of the present invention, in addition to the above effect, the resist mask is formed in a portion where no bump is formed and only the insulating film formed on the bump is removed through etching, which can eliminate a problem about the residual resin after the polishing.

Further, according to the twenty-second aspect of the present invention, in addition to the effect described in the inventions from 14 to 38, the insulating film is wholly etched and removed to such an extent that the top face of the bump is exposed, which can eliminate a problem about the residual resin after the polishing. In addition, there is no need to form the resist mask, whereby the step of forming the resist mask can be omitted.

Further, according to the twenty-third aspect of the present invention, in addition to the effect described in the inventions from 14 to 38, the insulating film is removed through the laser processing, which can eliminate a problem about the residual resin after the polishing.

Further, according to the thirty-fifth to thirty-seventh aspects of the present invention, in addition to the effect described in the inventions from 14 to 38, the resistor layer, the metal layer, and the dielectric layer are formed on one surface of the wiring circuit board and the wiring layer is formed on the other surface, whereby a signal circuit and a power source circuit in which passive elements are incorporated can be formed on the single wiring circuit board.

Further, according to the thirty-eighth aspect of the present invention, in addition to the effect described in the inventions from 14 to 38, the electromagnetic shielding sheet is formed on the wiring circuit board, whereby the electromagnetic wave generated from the wiring circuit board can be shielded and at the same time, cross-talk generated between the wiring layers can be reduced.

Also, according to the thirty-ninth to fifty-first aspects of the present invention, the highly integrated wiring circuit boards are laminated, whereby the highly integrated multilayer wiring circuit board or the highly integrated wiring circuit board can be manufactured.

### BRIEF DESCRIPTION OF THE DRAWINGS

In the accompanying drawings:

FIG. 1 is a sectional view showing a wiring circuit board according to a first embodiment of the present invention;

FIGS. 2A to 2H are sectional views of the wiring circuit board according to the first embodiment of the present invention, each of which illustrates a manufacturing method for the wiring circuit board in a manufacturing step order;

FIGS. 3A and 3B are sectional views of the wiring circuit board, each of which illustrates an example of how a semiconductor chip is mounted to the wiring circuit board;

FIG. 4 is a sectional view showing a manufacturing method for a wiring circuit board according to a second embodiment of the present invention;

FIGS. 5A to 5C are sectional views of the wiring circuit board according to the second embodiment of the present invention, each of which illustrates a manufacturing method for the wiring circuit board in a manufacturing step order;

FIGS. 6A to 6E are sectional views of a wiring circuit board according to a third embodiment of the present invention, each of which illustrates a manufacturing method for the wiring circuit board in a manufacturing step order;

FIG. 7 is a sectional view showing a wiring circuit board according to a fourth embodiment of the present invention;

FIGS. 8A to 8D are sectional views of the wiring circuit board according to the fourth embodiment of the present invention, each of which illustrates a manufacturing method for the wiring circuit board in a manufacturing step order;

FIG. 9 is a sectional view showing the wiring circuit board according to the fourth embodiment of the present invention;

FIGS. 10A to 10C are sectional views showing a circuit module according to a fifth embodiment of the present invention;

FIG. 11 is a sectional view showing a circuit module according to a sixth embodiment of the present invention;

FIG. 12 is a sectional view showing a circuit module according to a seventh embodiment of the present invention;

FIGS. 13A to 13I are sectional views of a wiring circuit board of a conventional technique, each of which illustrates a manufacturing method for the wiring circuit board in a manufacturing step order;

FIGS. 14A to 14G are sectional views of a wiring circuit board according to an eighth embodiment of the present invention, each of which illustrates a manufacturing method for the wiring circuit board in a manufacturing step order;

FIGS. 15A to 15E are sectional views of the wiring circuit board according to the eighth embodiment of the present invention, each of which illustrates the manufacturing method for the wiring circuit board in a manufacturing step order;

FIGS. 16A to 16F are sectional views of a wiring circuit board according to a ninth embodiment of the present invention, each of which illustrates a manufacturing method for the wiring circuit board in a manufacturing step order;

FIGS. 17A to 17F are sectional views of the wiring circuit board according to the ninth embodiment of the present invention, each of which illustrates the manufacturing method for the wiring circuit board in a manufacturing step order;

FIGS. 18A to 18E are sectional views of a wiring circuit board according to a tenth embodiment of the present invention, each of which illustrates a manufacturing method for the wiring circuit board in a manufacturing step order;

FIGS. 19A to 19E are sectional views of the wiring circuit board according to the tenth embodiment of the present invention, each of which illustrates the manufacturing method for the wiring circuit board in a manufacturing step order;

FIGS. 20A to 20D are sectional views of a wiring circuit board according to an eleventh embodiment of the present invention, each of which illustrates a manufacturing method for the wiring circuit board in a manufacturing step order;

FIGS. 21A to 21D are sectional views of a wiring circuit board according to a twelfth embodiment of the present invention, each of which illustrates a manufacturing method for the wiring circuit board in a manufacturing step order;

FIGS. 22A to 22C are sectional views of a wiring circuit board according to a thirteenth embodiment of the present invention, each of which illustrates a manufacturing method for the wiring circuit board in a manufacturing step order;

FIGS. 23A to 23D are sectional views of a wiring circuit board according to a fourteenth embodiment of the present invention, each of which illustrates a manufacturing method for the wiring circuit board in a manufacturing step order;

FIGS. 24A to 24F are sectional views of a wiring circuit board according to a fifteenth embodiment of the present invention, each of which illustrates a manufacturing method for the wiring circuit board in a manufacturing step order;

FIGS. 25A to 25E are sectional views of the wiring circuit board according to the fifteenth embodiment of the present invention, each of which illustrates the manufacturing method for the wiring circuit board in a manufacturing step order;

FIGS. 26A to 26C are sectional views of a wiring circuit board according to a sixteenth embodiment of the present invention, each of which illustrates a manufacturing method for the wiring circuit board in a manufacturing step order;

FIGS. 27A and 27B are sectional views of a wiring circuit board according to a seventeenth embodiment of the present invention, each of which illustrates a manufacturing method for the wiring circuit board in a manufacturing step order;

FIGS. 28A to 28D are sectional views of a wiring circuit board according to an eighteenth embodiment of the present invention, each of which illustrates a manufacturing method for the wiring circuit board in a manufacturing step order;

FIGS. 29A to 29E are sectional views of the wiring circuit board according to the eighteenth embodiment of the present invention, each of which illustrates the manufacturing method for the wiring circuit board in a manufacturing step order;

FIGS. 30A to 30E are sectional views of a wiring circuit board according to a nineteenth embodiment of the present invention, each of which illustrates a manufacturing method for the wiring circuit board in a manufacturing step order;

FIGS. 31A to 31F are sectional views of the wiring circuit board according to the nineteenth embodiment of the present invention, each of which illustrates the manufacturing method for the wiring circuit board in a manufacturing step order;

FIGS. 32A to 32E are sectional views of a wiring circuit board according to a twentieth embodiment of the present invention, each of which illustrates a manufacturing method for the wiring circuit board in a manufacturing step order; and

FIGS. 33A to 33F are sectional views of the wiring circuit board according to the twentieth embodiment of the present invention, each of which illustrates the manufacturing method for the wiring circuit board in a manufacturing step order.

### DETAILED DESCRIPTION OF THE PREFERRED EMBODIMENTS

Basically, the present invention provides, as a wiring circuit board used in a circuit module etc., a wiring circuit board in which a plurality of bumps are formed on a surface portion of a wiring layer directly or indirectly through an etching barrier layer, an insulating film is formed on the wiring layer at a portion where no bump is formed, and a solder ball is formed on a top face of the bump directly or indirectly through a wiring layer formed on the insulating film surface so as to connect with the bump. The bump is preferably made of copper because of satisfactory conductivity and mechanical strength. For that matter, a technique of forming the bump from copper and using the bump as an interlayer connection means has been already established by the applicants of the present invention.

A preferred embodiment of a wiring circuit board according to the present invention is a wiring circuit board including a bump formation region where the bumps are formed and a bump non-formation region where no bump is formed, the bump non-formation region serving as a flexible region and the bump formation region serving as a rigid region. As another preferred embodiment of the present invention, the top face of the bump is pressurized from above and flattened out prior to the formation of the insulating film to enlarge the top face of the bump. Enlarging the top face of the bump leads to a wide connection area between the bump and the solder ball, a high connection strength, and an improved reliability thereof.

As still another preferred embodiment of the present invention, the top face of the bump is formed in a rounded concave shape by etching, for example, and the solder ball is directly formed on the top face of the bump. This is because the connection area between the bump and the solder ball can be further widened and the solder ball inroads the board to further enhance the connection strength. As a result, a reliability of the wiring circuit board can be further enhanced and a service life thereof can be prolonged.

Note that forming the top face of the bump in a rounded concave shape is applicable to all embodiments in which the solder ball is directly formed on the top face of the bump.

(First Embodiment)

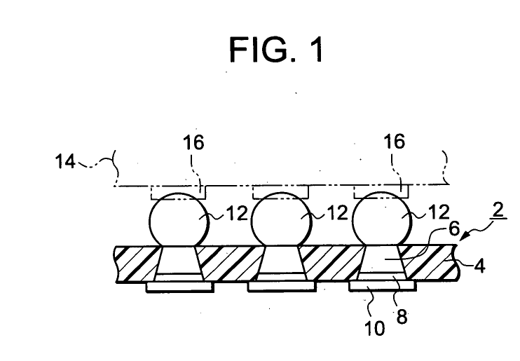

Referring to FIG. 1, description is given of a wiring circuit board according to a first embodiment of the present invention. FIG. 1 is a sectional view showing the wiring circuit board according to the first embodiment of the present invention.

As shown in FIG. 1, a wiring circuit board 2 according to the first embodiment includes: an insulating film 4; a bump 6; an etching barrier layer 8; and a wiring layer 10. The insulating film 4 is made of a polyimide resin. The bump 6 is made of copper and formed to penetrate the insulating film 4. The bump 6 has a conical shape. To be specific, the bump 6 has a circular shape in cross-section and has a substantially trapezoidal shape in vertical section. Note that the trapezoidal shape in vertical section of the bump 6 is shown for convenience of illustration; oblique sides thereof may be curved. In addition, the shape in vertical section may be a substantially rectangle. The bump 6 may take a substantially cylindrical shape, in addition to the substantially conical shape. Even in such a case, the oblique sides thereof may be curved. The top face of each bump 6 is exposed at the surface of the insulating film 4 while being flush with the surface of the insulating film.

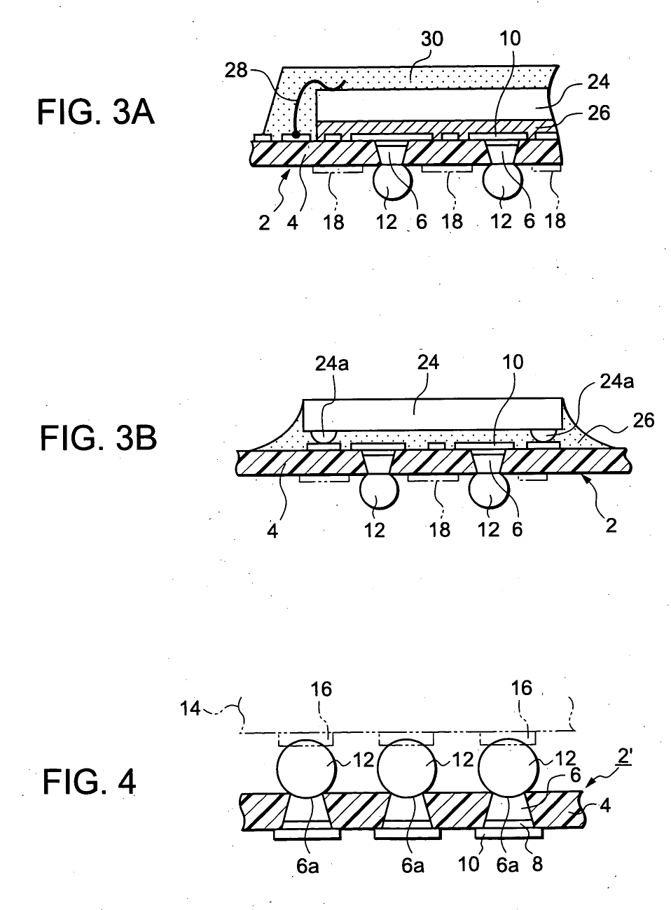

The etching barrier layer 8 is made of nickel (Ni) and formed underneath the bump 6. The wiring layer 10 is made of copper. Each bump 6 is connected to the wiring layer 10 through the etching barrier layer 8. Note that as the wiring layer 10, a copper film whose surface is coated with gold, silver, rhodium, tin, solder, aluminum, or the like may be used. Although not shown, the wiring layer 10 is connected to an electrode of a semiconductor chip or an IC with a solder ball (flip chip) is connected directly or indirectly through a bonding wire. The connection form is described later with reference to FIGS. 3A and 3B.

The solder ball 12 is formed on the top face of each bump 6. A printed circuit board 14 is a rigid board connected to the wiring circuit board 2. The wiring layer 16 is formed on the surface of the printed circuit board 14.

Each wiring layer 16 is connected to each bump 6 through the solder ball 12 and thus the wiring circuit board 2 is mounted to the printed circuit board 14. As a result, a circuit module composed of the wiring circuit board 2 and the printed circuit board 14 is manufactured. The wiring circuit board 2 is thin and flexible, whereas the printed circuit board 14 is rigid. Therefore, the circuit module has the rigid printed circuit board 14 and the flexible wiring circuit board 2 combined and incorporated therein. Accordingly, the circuit module can be attained, in which an electrode, a terminal, or the like of the rigid printed circuit board 14, for example, is electrically led out with the flexible wiring circuit board 2.

With the wiring circuit board 2 according to this embodiment, the solder ball 12 is directly formed on the top face of each bump 6 exposed at the surface of the insulating film 4, which saves the trouble of forming a solder ball base film as a base for the solder ball. As a result, as compared with the conventional technique, the number of steps necessary for manufacturing the wiring circuit board 2 can be reduced.

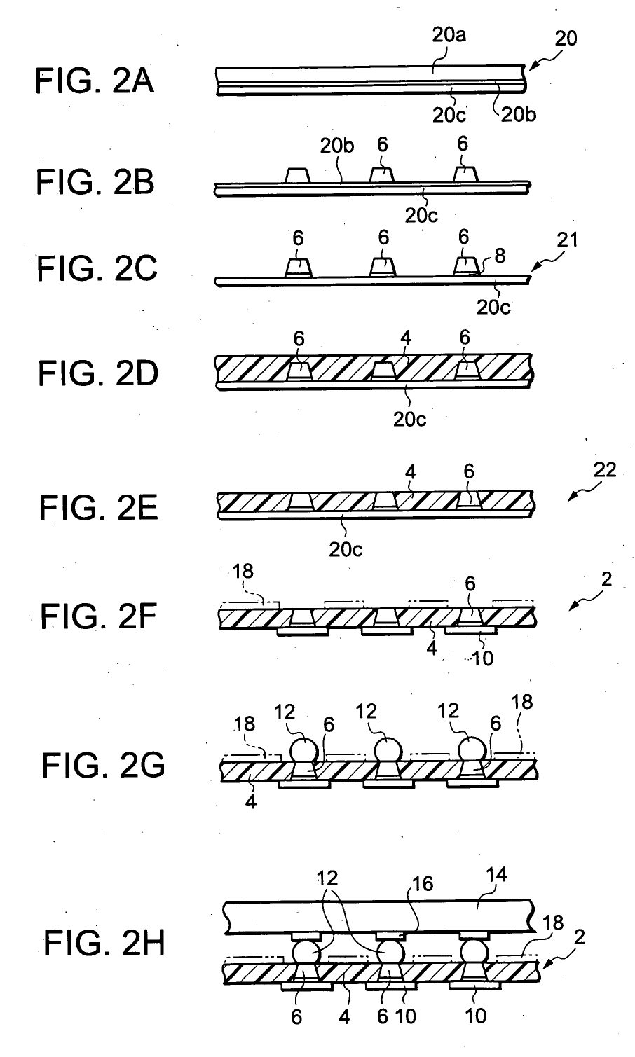

Referring next to FIGS. 2A to 2H, a manufacturing process for the wiring circuit board according to the first embodiment is described. FIGS. 2A to 2H are sectional views of the wiring circuit board according to the first embodiment of the present invention, each of which illustrates a manufacturing method for the wiring circuit board in the manufacturing step order.

As shown in FIG. 2A, a multilayer metal plate 20 is prepared. The multilayer metal plate 20 includes: a wiring layer forming metal layer 20c formed of copper with a thickness of 12 to 30 μm; an etching barrier layer 20b formed of nickel (Ni) with a thickness of 0.5 to 2.0 μm and laminated on the layer 20c; and a bump forming metal layer 20a formed of copper with a thickness of 20 to 80 μm and laminated on the layer 20b.

Next, a resist is applied onto the bump forming metal layer 20a, followed by exposure with an exposure mask with plural circular patterns, and development. A resist mask (not shown) is thus formed. Subsequently, as shown in FIG. 2B, the bump forming metal layer 20a is etched by using the resist mask as a mask to form the bump 6.

Next, as shown in FIG. 2C, the etching barrier layer 20b is removed through etching with the bump 6 used as a mask to thereby manufacture a bump-equipped board 21. At this point, the etching barrier layer 8 is interposed between the bump 6 and the wiring layer forming metal layer 20c.

As shown in FIG. 2D, a surface of the board on which the bump 6 is formed is coated with a liquid insulating material including a polyimide resin, an epoxy resin, or the like in a precursor form by a curtain coater method, a doctor blade method, a bar coater method, or a screen printing method, for example.

In this embodiment, the insulating material is applied to a level somewhat higher than the bump 6. The liquid insulating material is solidified by baking to form the insulating film 4. In the case of using the polyimide resin, the resin is baked while gradually raising a temperature up to about 400° C. (ultimate temperature) for imidization. In the case of using the epoxy resin as well, the resin is baked while gradually raising a temperature up to about 180° C. (ultimate temperature). FIG. 2D shows the insulating film 4 thus formed by baking.

Next, as shown in FIG. 2E, a surface portion of the insulating film 4 is polished sufficiently enough to completely expose at least the top face of each bump 6. A wiring circuit board 22 is thus manufactured. The polishing process equalizes a film thickness of the insulating film 4 and a height of the bump 6. Note that the top face of the bump 6 has only to be completely exposed. After the top face is exposed, the insulating film 4 may be continuously and additionally polished.

As the insulating material, a thermoplastic resin may be used in addition to the polyimide resin and the epoxy resin. Examples of the thermoplastic resin include a liquid crystal polymer (LCP), PEEK, PES, PPS, or PET. The resin is molded by using a T-die method. The T-die method includes: extruding a heat-melted resin by an extruder; applying the resin from a T-die at a tip; directly coating the bump-equipped board 21 with the material (resin) in the fluid form; and cooling and solidifying the material. The thermoplastic resin such as the liquid crystal polymer is applied to the board using the T-die method, and cooled and solidified to form the insulating film 4.

A resist is applied onto the wiring layer forming metal layer 20c, followed by exposure and development to thereby form a resist mask (not shown). For example, a positive resist is applied, and an exposure mask with a predetermined pattern is used to expose the resist according to the mask pattern. In this embodiment, the resist located between the adjacent bumps 6 is exposed. Thereafter, the exposed resist is removed through the development so as to leave the resist mask (not shown) only underneath each bump 6. As shown in FIG. 2F, the wiring layer forming metal layer 20c is etched by using the resist mask as a mask to thereby form the wiring layer 10. Each wiring layer 10 is connected to the bump 6 through the etching barrier layer 8. In this way, the wiring circuit board 2 according to the first embodiment is manufactured.

Note that, as indicated by a chain double-dashed line in the figures, a dam 18 may be formed of a solder resist, for example, before or after the formation of the wiring layer 10 with intent to even out a solder junction surface and to prevent short-circuit caused by drips.

Next, a spherical solder serving as a solder ball is placed on the top face of each bump 6 exposed at the surface of the insulating film 4. In this state, the wiring circuit board is set in a heating furnace where reflow processing is conducted, so that the solder ball 12 connected and secured to the bump 6 is formed. FIG. 2G shows a state thereof after reflow processing.

Note that the spherical solder may be placed by the following method. That is, prepared first is a jig capable of holding the spherical solder through vacuuming. Then, the jig that is holding the spherical solder is placed above each bump 6, followed by terminating the vacuuming of the jig. Hence, each spherical solder falls onto the top face of each bump 6 under its own weight. Then, the solder ball 12 is formed by reflow processing.

Alternatively, a solder cream may be printed onto the top face of the bump 6, followed by heat-reflow processing. The solder ball may be formed in this manner.

According to the manufacturing method for the wiring circuit board 2, the solder ball 12 can be directly formed on the top face of each bump 6 exposed at the surface of the insulating film 4. This makes it unnecessary to form the solder ball base film serving as the base for the solder ball 12. As a result, the number of steps necessary for manufacturing the wiring circuit board 2 can be reduced.

As shown in FIG. 2H, the wiring circuit board 2 can be mounted to the printed circuit board 14. In general, before the wiring circuit board 2 is mounted to the printed circuit board etc., the semiconductor chip, for example, is mounted to the wiring circuit board 2. In FIG. 2H, the semiconductor chip is omitted. Referring to FIGS. 3A and 3B, description is given of an example of how the semiconductor chip is mounted.

FIGS. 3A and 3B are sectional views showing an example of how the semiconductor chip is mounted to the wiring circuit board 2. FIG. 1 shows, as discussed earlier, an example in which the wiring circuit board is mounted to the rigid printed circuit board 14 as indicated by the chain double-dashed line. As shown in FIGS. 3A and 3B, the semiconductor chip can be directly mounted to the wiring circuit board 2.

FIG. 3A shows an example in which an electrode of a semiconductor chip 24 is connected to the wiring layer 10 of the wiring circuit board 2 by wire bonding. FIG. 3B shows an example in which an electrode 24a of the semiconductor chip 24 is directly connected to the wiring layer 10 of the wiring circuit board 2 to thereby mount the semiconductor chip 24 to the wiring circuit board 2.

Referring to FIG. 3A, an example of the mounting through wire bonding is explained. As shown in FIG. 3A, the semiconductor chip 24 such as an LSI is fixed to the wiring circuit board 2 with the aid of a die-bonding adhesive layer 26. A bonding wire 28 constituted of a gold wire etc. connects between the wiring layer 10 of the wiring circuit board 2 and the electrode of the semiconductor chip 24. Accordingly, each electrode is connected to any of the bumps 6 through the bonding wire 28 and the wiring layer 10. The bump 6 is connected to the solder ball 12 and thus each electrode is connected to the solder ball 12 through the bump 6 and electrically led out. The semiconductor chip 24 is sealed with a resin 30. In general, a potting resin resulting from an epoxy resin is used as the resin 30.

Referring to FIG. 3B, an example in which a flip-chip type IC is mounted is described. The solder- or gold-plated electrode 24a is formed on the semiconductor chip 24 such as an IC or an LSI. After the semiconductor chip 24 is mounted to the wiring circuit board 2, a sealing resin 26 is injected into a space therebetween and cured as necessary. Also, a gold stud bump may be formed on the semiconductor chip 24 and bonded to the wiring circuit board 2 through an anisotropic conductive adhesive (not shown). After the mounting, the resin 26 functions to glue the semiconductor chip 24 and the wiring circuit board 2 together and to seal the space therebetween.

(Second Embodiment)

Referring next to FIG. 4, a wiring circuit board according to a second embodiment of the present invention is described. FIG. 4 is a sectional view showing the wiring circuit board according to the second embodiment of the present invention. The wiring circuit board according to the second embodiment has the substantially same structure as that of the wiring circuit board according to the first embodiment shown in FIG. 1 except that a top face 6a of each bump 6 has a rounded concave shape. The solder ball 12 is formed to fit in the rounded concave face.

With a wiring circuit board 2′ according to the second embodiment, the top face 6a of each bump 6 has a rounded concave shape. Hence, a connection area between the top face 6a and the solder ball 12 increases. As a result, a connection strength is increased to enhance a reliability of the wiring circuit board itself and prolong its service life.

A step of quick-etching copper may be inserted between the step of FIG. 2F and the step of FIG. 2G of the steps discussed in the first embodiment for forming the rounded concave top face 6a of each bump 6.

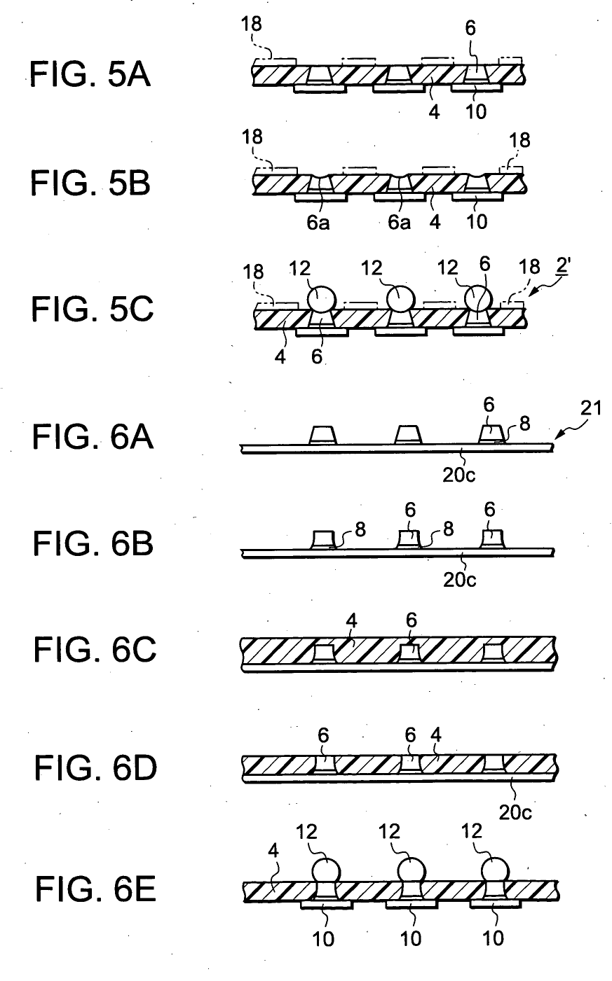

Referring now to FIGS. 5A to 5C, description is given of the step of forming the rounded concave face and its previous and subsequent steps. FIGS. 5A to 5C are sectional views of the board, each of which illustrates the steps of forming the rounded concave face in the manufacturing step order. The wiring layer 10 shown in FIG. 5A is obtained by selectively etching the wiring layer forming metal layer 20c shown in FIG. 2E. Note that before or after the wiring layer 10 is formed, the dam 18 may be formed, for example, of a solder resist as indicated by the chain double-dashed line to thereby even out a solder junction surface and to prevent short-circuit caused by drips.

Next, as shown in FIG. 5B, the top face 6a of each bump 6 is subjected to wet etching to form the rounded concave top face 6a. Next, as shown in FIG. 5C, the spherical ball serving as the solder ball is placed on the top face 6a of each bump 6. In this state, the wiring circuit board is set in a heating furnace where reflow processing is conducted to thereby form the solder ball 12 to be directly connected and secured to the top face 6a of each bump 6.

The addition of the wet etching step shown in FIG. 5B offers the wiring circuit board 2′ according to the second embodiment shown in FIG. 4. Note that forming the rounded concave top face 6a of each bump 6 is applicable to the example of the mounting of the semiconductor chip shown in FIGS. 3A and 3B and to all embodiments in which the solder ball 12 is directly formed on the bump 6 as well. Note that, description has been given of the case of etching the wiring layer 10 and the fop face 6a of each bump 6 in different steps. Both may be simultaneously subjected to wet etching instead, which is more efficient.

(Third Embodiment)

Referring next to FIGS. 6A to 6E, a manufacturing method for a wiring circuit board according to a third embodiment of the present invention is described. FIGS. 6A to 6E are sectional views of the wiring circuit board according to the third embodiment, each of which illustrates the manufacturing method for the wiring circuit board in the manufacturing step order. The manufacturing method for the wiring circuit board according to the third embodiment is a partial modification of the manufacturing method for the wiring circuit board according to the first embodiment.

As shown in FIG. 6A, the bump-equipped board 21 is prepared in which the bump 6 is formed on one surface of the wiring layer forming metal layer 20C through the etching barrier layer 20b. The board is manufactured according to the steps in the first embodiment as shown in FIGS. 2A to 2C. The manufacturing method for the board shown in FIG. 6A is hereinafter outlined.

First, the multilayer metal plate 20 is prepared in which the bump forming metal layer 20a is formed on one surface of the wiring layer forming metal layer 20c through the etching barrier layer 20b. The bump forming metal layer 20a is selectively etched to form the bump 6. After that, the etching barrier layer 20b is etched and removed by using the bump 6 as a mask. In this way, as shown in FIG. 6A, the bump-equipped board 21 is obtained.

Next, the respective bumps 6 are pressurized and flattened out at a time. As shown in FIG. 6B, a diameter of the top face of each bump 6 is increased. A reason for increasing the diameter of the top face of each bump 6 is to enhance the connection strength between the bump and the solder ball formed on the top face of each bump such that the solder ball is unlikely to slip off the bump.

There is an increasing demand for high-density arrangement of the bumps along with recent tendencies to narrow a pitch between the wiring layers of the wiring circuit board and to increase the number of electrodes of the IC, the LSI, or the like. As a result, a restriction is imposed on a size of the bump. Thus, in forming the bump, the diameter of the top face of the bump is restrained to about 70 μm in some cases.

However, in practice, unless the top face of the bump has the diameter of about 100 μm at the minimum, it is difficult to enhance a bonding strength between the solder ball and the bump to a satisfactory level. Accordingly, the solder ball and the bump are hardly bonded to each other with sufficiently high reliability.

To that end, the respective bumps 6 are collectively pressurized and flattened out to widen an area of the top face of each bump for enhancing the bonding strength between the solder ball and the bump. With this processing, the diameter of the top face of each bump 6 can be actually increased from about 70 μm to 100 μm or larger, for example.

Next, as shown in FIG. 6C, the insulating film 4 covering each bump 6 is formed. The step of forming the insulating film 4 is the same as the step in the first embodiment as shown in FIG. 2D. Next, as shown in FIG. 6D, the surface portion of the insulating film 4 is polished to such an extent as to expose at least the top face of each bump 6. Hence, the thickness of the insulating film 4 thus polished equals the height of the bump 6.

Then, as shown in FIG. 6E, the wiring layer forming metal layer 20c is selectively etched to thereby form the wiring layer 10 (similar to the step of FIG. 2F). After that, the solder ball 12 is formed on the top face of the bump 6 (similar to the step of FIG. 2G).

Note that, a dam may be formed of a solder resist, for example, before or after the formation of the wiring layer 10 with intent to even out a solder junction surface and to prevent short-circuit caused by drips.

As discussed above, the manufacturing method for the wiring circuit board shown in FIGS. 6A to 6E includes the step of increasing the diameter of the top face of the bump 6 by pressurizing each bump 6 from above and flattening out the bump. Therefore, the diameter of the top face of each bump 6 can be increased from about 70 μm to 100 μm or larger, for example. As a result, the bonding strength between each solder ball 12 and each bump 6 can be sufficiently enhanced with ease.

Note that in this embodiment, the etching barrier layer 20b is etched, followed by pressuring and flattening out each bump 6. However, the bump 6 may be pressurized prior to etching instead.

Also, after the step of FIG. 6D but before the step of FIG. 6E, the top face 6a of each bump 6 may be etched in a rounded concave shape through wet etching. This makes it possible to widen the connection area between the bump 6 and the solder ball 12 and to further enhance the connection strength. As a result, the high reliability of the wiring circuit board and the long service life can be attained.

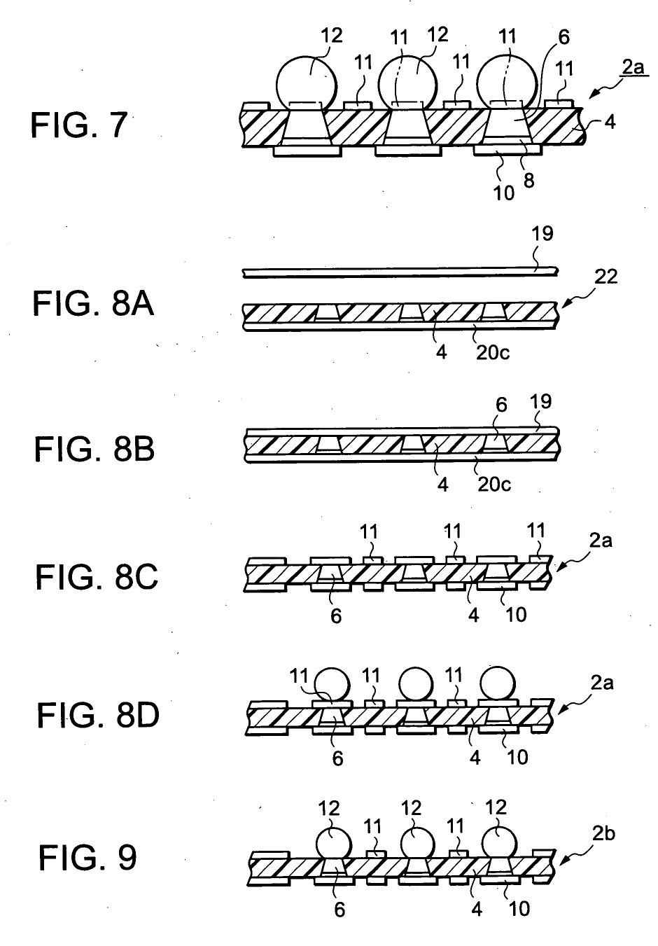

Referring next to FIG. 7, a wiring circuit board according to a fourth embodiment of the present invention is described. FIG. 7 is a sectional view showing the wiring circuit board according to the fourth embodiment of the present invention. The wiring circuit board according to this embodiment has a feature in that wiring layers are formed on both surfaces thereof. In the wiring circuit board 2 according to the first embodiment, the wiring layer 10 is formed on only a surface opposite to the surface where the solder ball 12 is formed (i.e., not formed on the surface where the solder ball 12 is formed).

As shown in FIG. 7, a wiring circuit board 2a according to this embodiment additionally has a wiring layer 11 formed on the surface where the solder ball 12 is formed. The solder ball 12 may be formed on the top face of each bump 6 directly or indirectly through the wiring layer 11 (as indicated by the chain double-dashed line in FIG. 7) in contact with the top face of each bump 6.

Referring next to FIGS. 8A to 8D, a manufacturing method for the wiring circuit board according to the fourth embodiment is described. FIGS. 8A to 8D are sectional views of the wiring circuit board according to the fourth embodiment of the present invention, each of which illustrates the manufacturing method for the wiring circuit board in the manufacturing step order.

As shown in FIG. 8A, the wiring circuit board 22 and a wiring layer forming metal layer 19 made of copper are prepared. As shown in FIG. 8B, the wiring layer forming metal layer 19 is laminated onto the wiring circuit board 22.

Next, as shown in FIG. 8C, the wiring layer forming metal layer 20c and the wiring layer forming metal layer 19 are selectively etched at a time to thereby form the wiring layer 10 and the wiring layer 11. In this way, the wiring circuit board 2a having the wiring layers on both surfaces is manufactured. Subsequently, as shown in FIG. 8D, the solder ball 12 is formed on the wiring layer 11 connected to the bump 6. As shown in FIG. 8D, the solder ball 12 may be formed on the wiring layer 11 connected to the bump 6 or directly formed on the top face of the bump 6 without forming the wiring layer 11 on the bump 6. That is, the wiring layer forming metal layer 19 may be selectively etched such that the wiring layer 11 is not formed on the bump 6 but formed only between the top faces of the bumps 6.

FIG. 9 is a sectional view of a wiring circuit board 2b in which the solder ball 12 is directly formed on the top face of each bump 6. As shown in FIG. 9, in the wiring circuit board 2b, the wiring layer 11 is not formed on the top face of each bump 6. Thus, the solder ball 12 is directly formed on the top face of each bump 6.

(Fifth Embodiment)

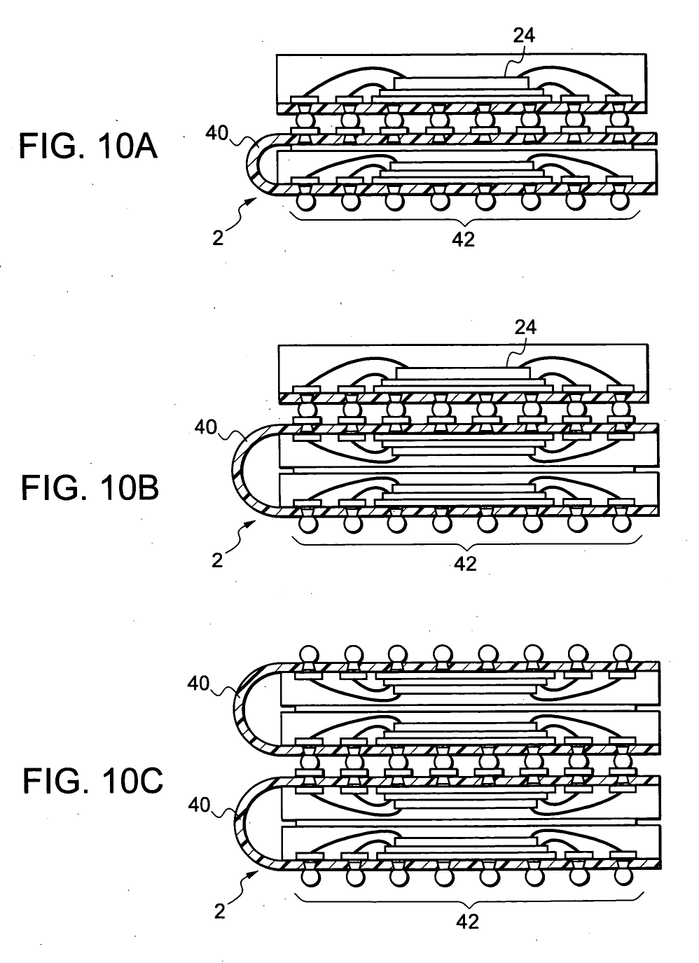

Referring next to FIGS. 10A to 10C, a circuit module using the wiring circuit board according to a fifth embodiment of the present invention is described. FIGS. 10A to 10C are sectional views of the circuit module according to the fifth embodiment.

The circuit module according to this embodiment adopts the flexible wiring circuit board. As shown in FIGS. 10A to 10C, formed are a region (hereinafter, referred to as a bump formation region 42) in which the bump 6 is formed and a region (hereinafter, referred to as a bump non-formation region 40) in which the bump 6 is not formed. The bump non-formation region 40 is made flexible. The wiring circuit board 2 is bent at the flexible portion and the semiconductor chip 24 such as the LSI is connected to the wiring circuit board 2.

As mentioned above, the bump non-formation region 40 is set on the wiring circuit board 2, making the board bendable at that portion. Thus, manufactured is the circuit module where the board can be arbitrarily bent when in use. Accordingly, the semiconductor chips 24 such as the LSI can be stereoscopically arranged. As a result, the numerous semiconductor chips 24 can be arranged in a limited space at a high density. Note that in this embodiment as well, the wiring circuit board 2′ having the top face 6a of the bump 6 in a rounded concave shape may be used.

(Sixth Embodiment)

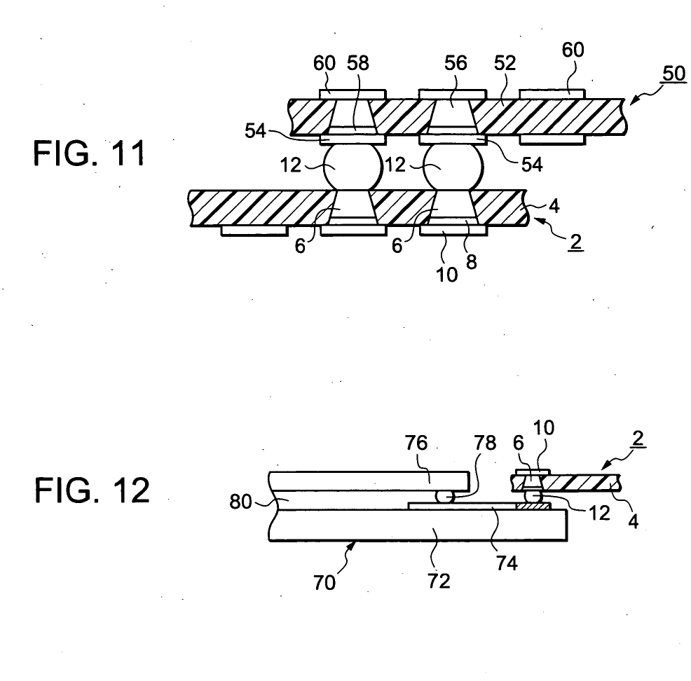

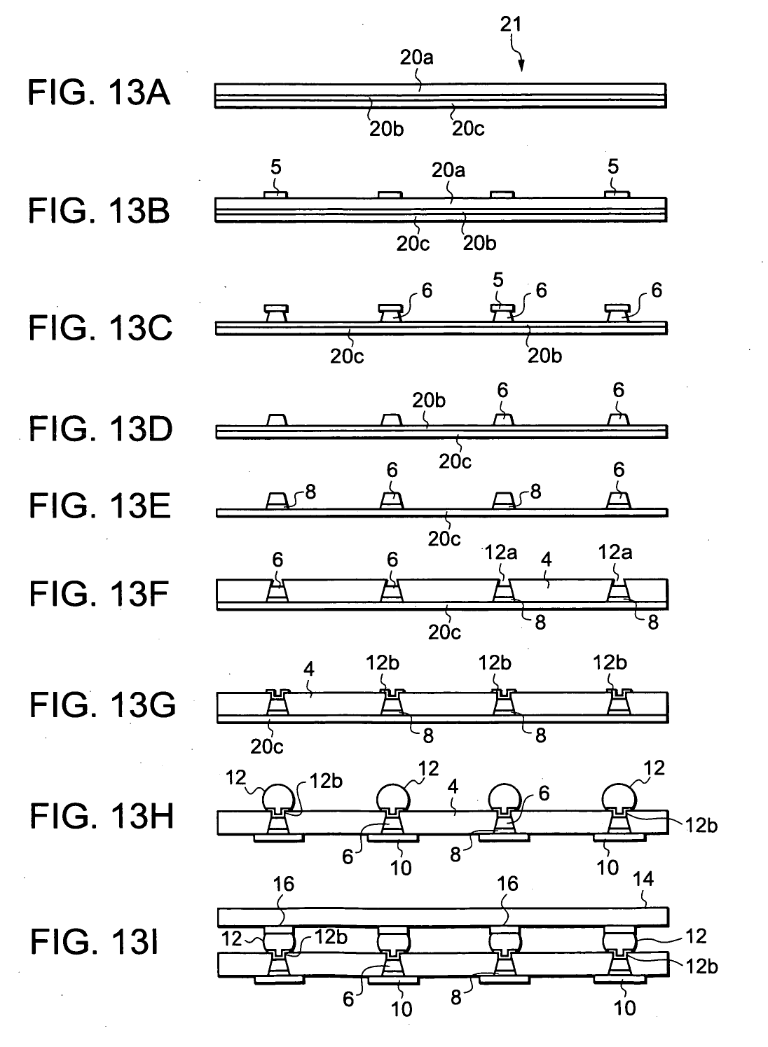

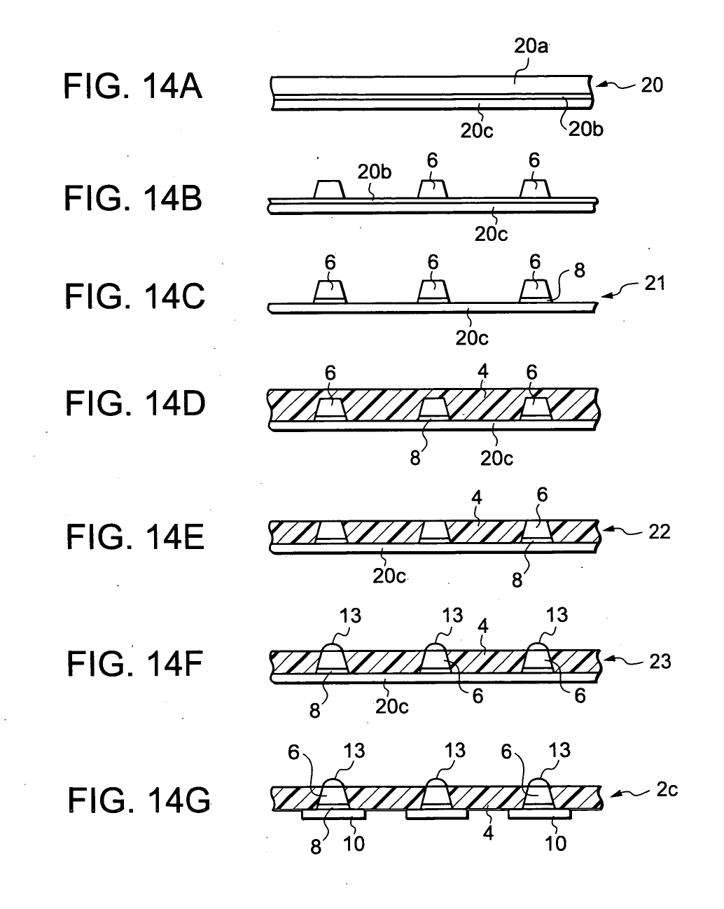

Referring next to FIG. 11, another circuit module using the wiring circuit board according to a sixth embodiment of the present invention is described. FIG. 11 is a sectional view of the circuit module according to the sixth embodiment of the present invention.

As shown in FIG. 11, the circuit module according to this embodiment is constituted of the wiring circuit board 2 and a wiring circuit board 50 as another board. The wiring circuit board 2 and the wiring circuit board 50 are connected to each other through the solder ball 12. In the wiring circuit board 50, an insulating film 52 has a wiring layer 54 formed of copper on one surface and a wiring layer 60 formed of copper on the other surface. A bump 56 is formed so as to penetrate the insulating film 52 and connected to the wiring layer 54 and the wiring layer 60. An etching barrier layer 58 is formed between a bottom face of the bump 56 and the wiring layer 54. Accordingly, the bump 56 is connected to the wiring layer 54 through the etching barrier layer 58. Also, at least part of the wiring layer 60 is formed while being connected to the top face of the bump 56.

The wiring circuit board 50 is formed by almost the same method as the wiring circuit board 2. The wiring circuit board 50 and the wiring circuit board 2 differ merely in the way of forming the wiring layer. That is, the wiring layer 10 is formed on only one surface of the insulating film 4 in the wiring circuit board 2, whereas the wiring layer 54 and the wiring layer 60 are formed on both surfaces of the insulating film in the wiring circuit board 50.

The wiring circuit board 2 and the wiring circuit board 50 are connected to each other through the solder ball 12 to compose the circuit module. A flexible board is used for the wiring circuit board 2 and the wiring circuit board 50. Hence, the circuit module in which the flexible wiring circuit boards are connected to each other can be readily attained.

(Seventh Embodiment)

Referring next to FIG. 12, another circuit module using the wiring circuit board according to a seventh embodiment of the present invention is described. FIG. 12 is a sectional view of the circuit module (liquid crystal device).

The circuit module according to this embodiment is a liquid crystal device in which the wiring circuit board 2 according to the first embodiment is connected to a rigid glass wiring board. In FIG. 12, a liquid crystal device (circuit module) 70 has a glass wiring board 72 on which a counter glass plate 76 is placed through a sealing member 78. A liquid crystal 80 is filled between the glass wiring board 72 and the counter glass plate 76. A transparent wiring 74 made of an indium tin oxide (ITO) film is formed on a surface of the glass wiring board 72. Further, a metal (e.g., copper, aluminum, titanium, nickel, tin, or silver) film may be formed on the ITO film surface. The wiring circuit board 2 is connected to the glass wiring board 72 through the solder ball 12. The solder ball 12 is connected to the transparent wiring 74.

The bump 6 of the wiring circuit board 2 is connected to an end of the transparent wiring 74 of the glass wiring board 72 through the solder ball 12, so that the glass wiring board 72 and the wiring circuit board 2 are connected to each other.

In this way, the glass wiring board 72 is connected to the wiring circuit board 2, by which the liquid crystal device where the flexible wiring circuit board 2 is used for leading out the electrode can be provided. Also, the wiring circuit board 2′ having the rounded concave top face of the bump may be used for the circuit module according to this embodiment. Note that the foregoing circuit module is taken as an example of the circuit module using the wiring circuit board of the present invention and hence, the present invention is not limited to the circuit module according to the above embodiments.

Next, a wiring circuit board with no solder ball 12 is discussed.

(Eighth Embodiment)

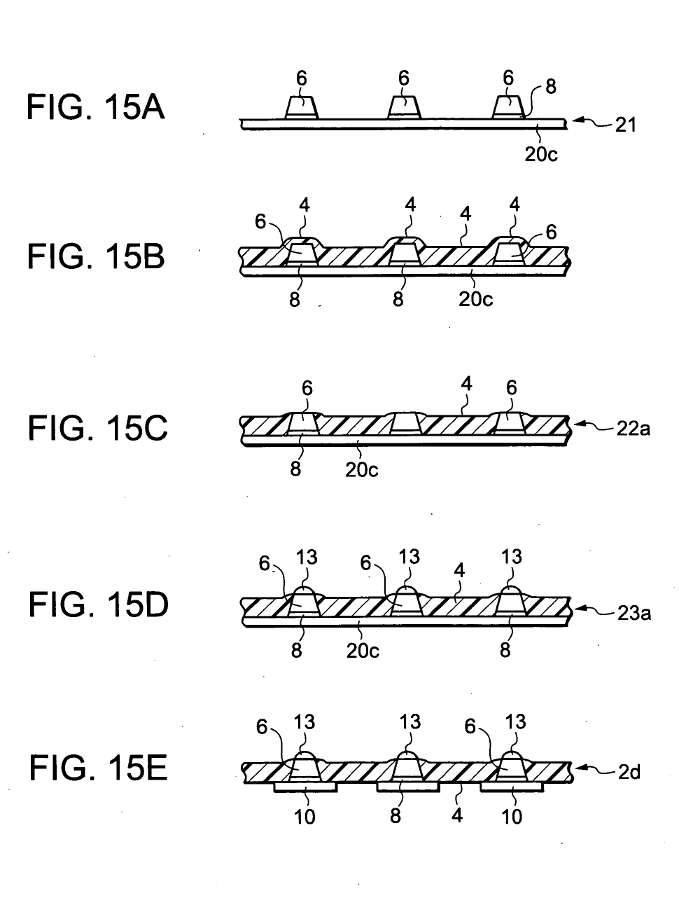

Referring to FIGS. 14A to 14G and FIGS. 15A to 15E, a manufacturing method for a wiring circuit board according to an eighth embodiment of the present invention is described. FIGS. 14A to 14G and FIGS. 15A to 15E are sectional views of the wiring circuit board according to the eighth embodiment of the present invention, each of which illustrates the manufacturing method for the wiring circuit board in the manufacturing step order.

As shown in FIG. 14A, the multilayer metal plate 20 is prepared. The multilayer metal plate 20 includes: the wiring layer forming metal layer 20c formed of copper with a thickness of 12 to 30 μm; the etching barrier layer 20b formed of nickel (Ni) with a thickness of 0.5 to 2.0 μm and laminated on the layer 20c; and the bump forming metal layer 20a formed of copper with a thickness of 20 to 80 μm and laminated on the layer 20b.

Next, a resist is applied onto the bump forming metal layer 20a, followed by exposure using an exposure mask with plural circular patterns and development. Thus, a resist mask (not shown) is formed. As shown in FIG. 14B, the bump forming metal layer 20a is etched by using the resist mask as a mask to thereby form the bump 6.

Subsequently, as shown in FIG. 14C, the etching barrier layer 20b is removed by etching using the bump 6 as a mask. Thus, the bump-equipped board 21 is manufactured. At this point, the etching barrier layer 8 is interposed between the bump 6 and the wiring layer forming metal layer 20c.

As shown in FIG. 14D, one surface of the board on which the bump 6 is formed is coated with a liquid insulating material including a polyimide resin, an epoxy resin, or the like in a precursor form by a curtain coater method, a doctor blade method, a bar coater method, or a screen printing method, for example. In this embodiment, the insulating material is applied to a level somewhat higher than the bump 6. The liquid insulating material is solidified by baking to form the insulating film 4. In the case of using the polyimide resin, the resin is baked while gradually raising a temperature up to about 400° C. (ultimate temperature). In the case of using the epoxy resin, the resin is baked while gradually raising a temperature up to about 180° C. (ultimate temperature). FIG. 14D shows the insulating film 4 thus formed by baking.

Next, as shown in FIG. 14E, a surface portion of the insulating film 4 is polished to such an extent as to completely expose at least the top face of each bump 6. The wiring circuit board 22 is thus manufactured. The polishing process equalizes the thickness of the insulating film 4 and the height of the bump 6. Note that the top face of the bump 6 has only to be completely exposed. After the top face is exposed, the insulating film 4 may be continuously and additionally polished.

As the insulating material, a thermoplastic resin may be used in addition to the polyimide resin and the epoxy resin. Examples of the thermoplastic resin include a liquid crystal polymer (LCP), PEEK, PES, PPS, or PET. The resin is molded by using a T-die method. The T-die method includes: extruding a heat-melted resin by an extruder; applying the resin from a T-die at a tip; directly coating the bump-equipped board 21 with the material (resin) in the fluid form; and cooling and solidifying the material. The thermoplastic resin such as the liquid crystal polymer is applied to the board using the T-die method, and cooled and solidified to form the insulating film 4.

Next, as shown in FIG. 14F, a protrusion 13 made of metal such as copper (Cu), gold (Au), silver (Ag), nickel (Ni), lead (Pb), platinum (Pt), or tin (Sn) or a metal alloy mainly containing the above metal is formed on the top face of each bump 6 to form a wiring circuit board 23.

Next, a resist is applied onto the wiring layer forming metal layer 20c, followed by exposure and development to thereby form a resist mask (not shown). For example, a positive resist is applied, and an exposure mask with a predetermined pattern is used to expose the resist according to the mask pattern. In this embodiment, the resist located between the adjacent bumps 6 is exposed. Thereafter, the exposed resist is removed through the development so as to leave the resist mask (not shown) only underneath each bump 6. As shown in FIG. 14G, the wiring layer forming metal layer 20c is etched by using the resist mask as a mask to thereby form the wiring layer 10. Each wiring layer 10 is connected to the bump 6 through the etching barrier layer 8. In this way, a wiring circuit board 2c is manufactured.

With the above-mentioned method, in forming the insulating film 4, the heat-pressing process can be omitted unlike the conventional cases. This obviates the necessity to provide any heat-pressing apparatus and also to conduct the heat-pressing process for a long time, making it possible to improve the productivity of the wiring circuit board.

The wiring layer forming metal layer does not need to pressurize and flatten out the bump 6 for the lamination on the bump 6, which obviates the necessity to make the bump 6 higher. As a result, the height of the bump 6 can approximate the thickness of the insulating film 4, which eliminates the need for the formation of the bump 6 higher than necessary. Accordingly, fine etching is realized. A distance between the adjacent bumps 6 can be shortened, making it possible to manufacture the highly integrated wiring circuit board.

For example, in the conventional technique, the bump 6 should have the height of about 80 to 150 μm, whereas in this embodiment, the height can be reduced down to about 20 to 80 μm although depending on the thickness of the insulating film 4 since it is unnecessary to pressurize and flatten out the bump. As a result, in the conventional technique, the distance between the adjacent bumps 6 should be set to about 250 to 400 μm, whereas in the present invention, the distance can be set to about 60 to 200 μm. A highly integrated wiring circuit board can be accordingly manufactured.

Also, there is an advantage in that, in the case of electrolytic plating (electroconductive plating), a plating precipitated on the top face of the bump 6 is observed to thereby confirm whether or not an exposed portion of each bump 6 is electrically connected.

Note that in this embodiment, as shown in FIG. 14D, the insulating film 4 is formed to a level somewhat higher than the bump 6 and then polished such that the insulating film 4 and the top face of the bump 6 are flush with each other. However, the present invention is not limited to this; the insulating film 4 may be formed to a level somewhat lower than the bump 6. Referring to FIGS. 15A to 15E, a method therefor is described.

As shown in FIG. 15A, the bump-equipped board 21 is prepared. Next, as shown in FIG. 15B, one surface of the board on which the bump 6 is formed is coated with a liquid insulating material including a polyimide resin, an epoxy resin, or the like in a precursor form by a curtain coater method, a doctor blade method, a bar coater method, or a screen printing method. At this point, the insulating material is applied to a level somewhat lower than the bump 6. As shown in FIG. 15B, the liquid resin is cured and contracted and a volatile component volatizes, so that the insulating material remains on the top face of the bump 6 in a slight amount. The liquid insulating material is solidified by baking to form the insulating film 4. As a result, the insulating film 4 is also formed on the bump 6. FIG. 15B shows the insulating film 4 thus formed by baking. Note that as discussed above, the thermoplastic resin such as the liquid crystal polymer or PET may be used as the insulating material. In the case of using the thermoplastic resin, it is unnecessary to perform baking.

Next, as shown in FIG. 15C, the insulating film 4 on the bump 6 is polished to such an extent as to completely expose at least the top face of the bump 6. A wiring circuit board 22a is thus manufactured. The insulating film 4 located between the bumps 6 has the thickness smaller than the height of the bump 6 and thus is not polished. The thickness of the insulating film 4 is smaller than the height of the bump 6 through the above polishing.

Next, as shown in FIG. 15D, the protrusion 13 made of metal is formed on the top face of each bump 6 by plating to thereby manufacture a wiring circuit board 23a. As shown in FIG. 15E, the wiring layer forming metal layer 20c is etched and patterned to form the wiring layer 10. A wiring circuit board 2d is thus manufactured.

Note that in this embodiment, the wiring layer 10 is formed after the protrusion 13 is formed. However, the protrusion 13 may be formed after the wiring layer 10 is formed.

(Ninth Embodiment)

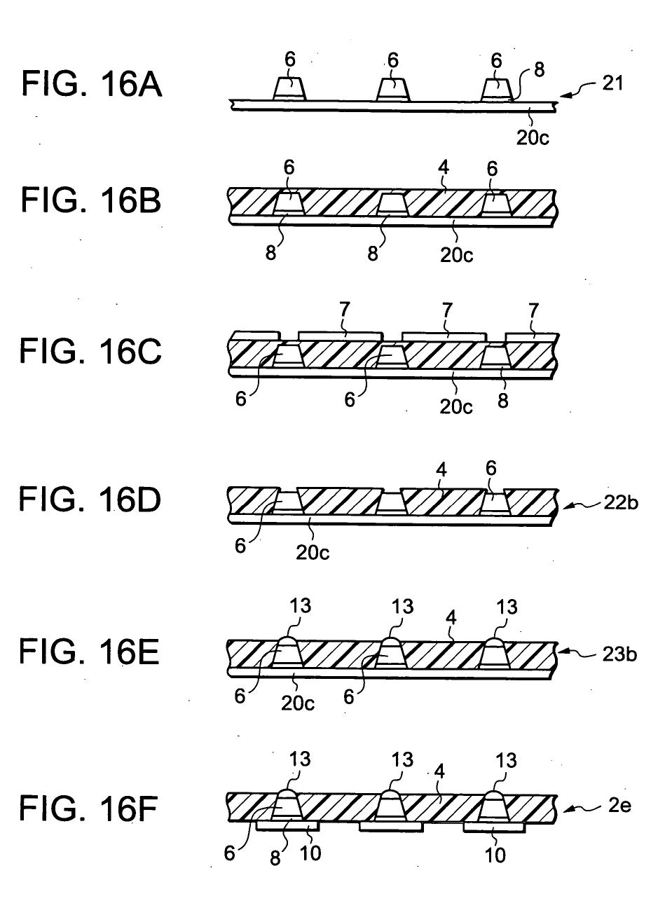

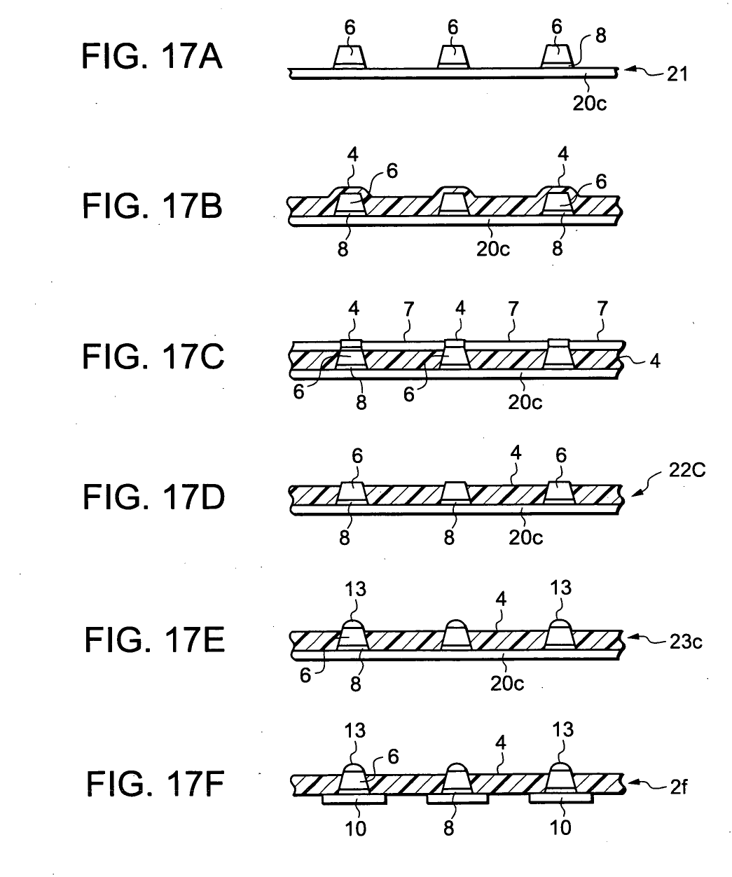

Referring next to FIGS. 16A to 16F and FIGS. 17A to 17F, a manufacturing method for a wiring circuit board according to a ninth embodiment of the present invention is described. FIGS. 16A to 16F and FIGS. 17A to 17F are sectional views of the wiring circuit board according to the ninth embodiment of the present invention, each of which illustrates the manufacturing method for the wiring circuit board in the manufacturing step order.

As shown in FIG. 16A, the bump-equipped board 21 is prepared. Next, as shown in FIG. 16B, one surface of the board on which the bump 6 is formed is coated with a liquid insulating material including a polyimide resin, an epoxy resin, or the like in a precursor form by a curtain coater method, a doctor blade method, a bar coater method, or a screen printing method. In this embodiment, the insulating material is applied to a level somewhat higher than the bump 6. The liquid insulating material is solidified by baking to form the insulating film 4. FIG. 16B shows the insulating film 4 thus formed by baking.

Next, as shown in FIG. 16C, a resist is applied onto the insulating film 4, followed by exposure and development to form the resist mask 7. For example, a positive resist is applied, and an exposure mask with a predetermined pattern is used to expose the resist on each bump 6. After that, the resist on each bump 6 is removed through development. The resist mask 7 is left only between the bumps 6.

Next, as shown in FIG. 16D, the insulating film 4 on each bump 6 is removed through etching by using the resist mask 7 as a mask to such an extent as to completely expose the top face of the bump 6. Thereafter, the resist mask 7 is peeled off to manufacture a wiring circuit board 22b. At this time, the thickness of the insulating film 4 is larger than the height of the bump 6.

Next, as shown in FIG. 16E, the protrusion 13 made of metal such as copper (Cu), gold (Au), silver (Ag), nickel (Ni), lead (Pb), platinum (Pt), or tin (Sn) or a metal alloy mainly containing the above metal is formed on the top face of each bump 6 to manufacture a wiring circuit board 23b.

Next, a resist is applied onto the wiring layer forming metal layer 20c, followed by exposure and development to thereby form a resist mask (not shown). For example, a positive resist is applied, and an exposure mask with a predetermined pattern is used to expose the resist according to the mask pattern. In this embodiment, the resist located between the adjacent bumps 6 is exposed. Thereafter, the exposed resist is removed through development so as to leave the resist mask (not shown) only underneath each bump 6. As shown in FIG. 16F, the wiring layer forming metal layer 20c is etched by using the resist mask as a mask to thereby form the wiring layer 10. Each wiring layer 10 is connected to the bump 6 through the etching barrier layer 8. In this way, a wiring circuit board 2e is manufactured.

With the aforementioned method, the heat-pressing process is unnecessary, which enhances the productivity of the wiring circuit board. Also, a distance between the adjacent bumps 6 can be shortened, making it possible to manufacture the highly integrated wiring circuit board. In addition, the manufacturing method according to this embodiment obviates the necessity to polish the insulating film 4 for exposing the top face of the bump 6. When polishing the resin insulating film 4, anyhow, the film is polished roughly. As a result, the resin slightly remains on the board, which involves subsequent troublesome process. In contrast, with the method according to this embodiment, the insulating film 4 is removed by etching without leaving the resin on the top face of the bump 6. Consequently, the subsequent process is more easily conducted.

As shown in FIG. 16B, in this embodiment, the insulating film 4 is formed to a level somewhat higher than the bump 6. Thereafter,

the insulating film 4 on the bump 6 is removed through etching. However, the present invention is not limited to this. The insulating film 4 may be formed to a level somewhat lower than the bump 6. Referring to FIGS. 17A to 17F, a method therefor is described.

As shown in FIG. 17A, the bump-equipped board 21 is prepared. Next, as shown in FIG. 17B, one surface of the board on which the bump 6 is formed is coated with a liquid insulating material in a precursor form by a curtain coater method, a doctor blade method, a bar coater method, or a screen printing method. At this point, the insulating material is applied to a level somewhat lower than the bump 6. As shown in FIG. 17B, the liquid resin is cured and contracted and a volatile component volatizes, so that the insulating material remains on the top face of the bump 6 in a slight amount. The liquid insulating material is solidified by baking to form the insulating film 4. As a result, the insulating film 4 is formed also on the bump 6. FIG. 17B shows the insulating film 4 thus formed by baking.

Next, as shown in FIG. 17C, a resist is applied onto the insulating film 4, followed by exposure and development to form the resist mask 7. For example, a positive resist is applied, and an exposure mask with a predetermined pattern is used to expose the resist on each bump 6. After that, the resist on each bump 6 is removed through development. The resist mask 7 is left only between the bumps 6.

Next, as shown in FIG. 17D, the insulating film 4 on each bump 6 is removed through etching by using the resist mask 7 as a mask to such an extent as to completely expose the top face of each bump 6. Thereafter, the resist mask 7 is peeled off to manufacture a wiring circuit board 22c. At this time, the thickness of the insulating film 4 is smaller than the height of the bump 6.

Next, as shown in FIG. 17E, the protrusion 13 made of metal is formed on the top face of each bump 6 by plating to thereby manufacture a wiring circuit board 23c. As shown in FIG. 17F, the wiring layer forming metal layer 20c is etched and patterned to form the wiring layer 10. A wiring circuit board 2f is thus manufactured.

Note that in this embodiment as well, similar to the eighth embodiment, as the insulating material, the thermoplastic resin such as the liquid crystal polymer or PET may be used in addition to the polyimide resin. Here, the wiring layer 10 is formed after the protrusion 13 is formed. However, the wiring layer 10 may be first formed and then, electroless plating is conducted or a conductive paste is printed to thereby form the protrusion 13.

(Tenth Embodiment)

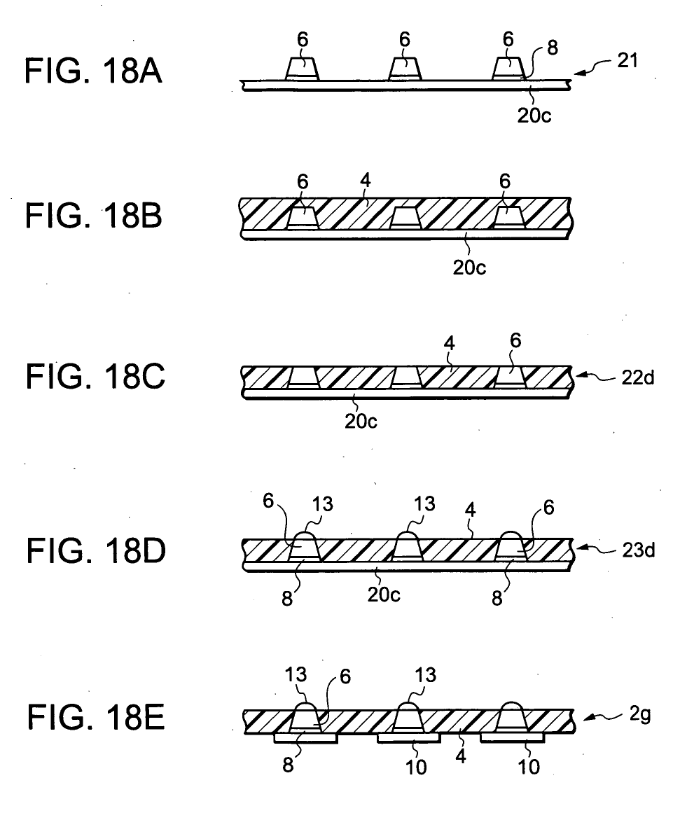

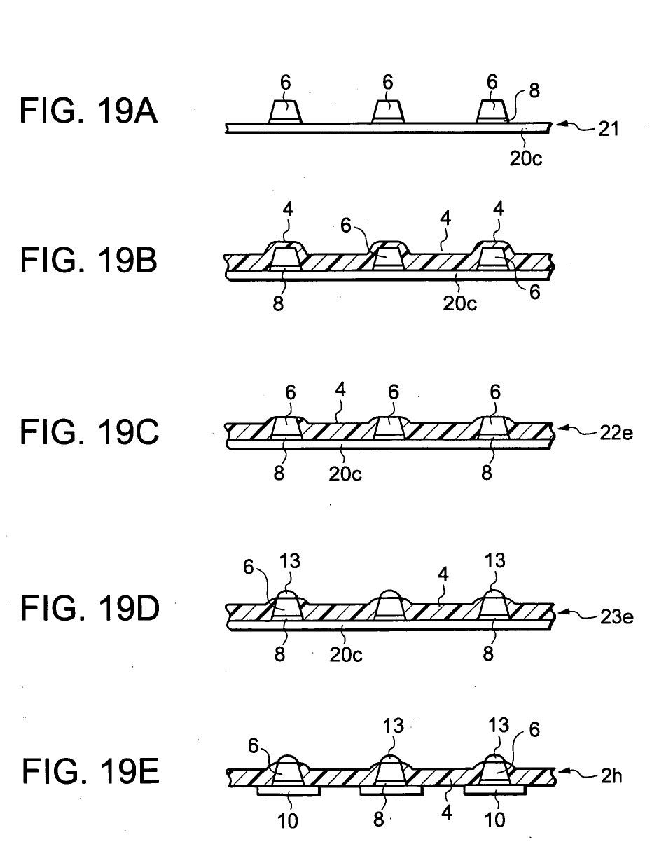

Referring next to FIGS. 18A to 18E and FIGS. 19A to 19E, a manufacturing method for a wiring circuit board according to a tenth embodiment of the present invention is described. FIGS. 18A to 18E and FIGS. 19A to 19E are sectional views of the wiring circuit board according to the tenth embodiment of the present invention, each of which illustrates the manufacturing method for the wiring circuit board in the manufacturing step order.

As shown in FIG. 18A, the bump-equipped board 21 is prepared. Next, as shown in FIG. 18B, one surface of the board on which the bump 6 is formed is coated with a liquid insulating material including a polyimide resin, an epoxy resin, or the like in a precursor form by a curtain coater method, a doctor blade method, a bar coater method, or a screen printing method, for example. In this embodiment, the insulating material is applied to a level somewhat higher than the bump 6. The liquid insulating material is solidified by baking to form the insulating film 4. FIG. 18B shows the insulating film 4 thus formed by baking.

Next, as shown in FIG. 18C, the insulating film 4 is wholly removed through etching to such an extent as to completely expose at least the top face of each bump 6. A wiring circuit board 22d is thus manufactured. At this time, the thickness of the insulating film 4 substantially equals the height of the bump 6. Note that the top face of the bump 6 has only to be completely exposed. After the top face is exposed, the insulating film 4 may be continuously and additionally etched. In such a case, the thickness of the insulating film 4 is smaller than the height of the bump 6.

Next, as shown in FIG. 18D, the protrusion 13 made of metal such as copper (Cu), gold (Au), silver (Ag), nickel (Ni), lead (Pb), platinum (Pt), or tin (Sn) or a metal alloy mainly containing the above metal is formed on the top face of each bump 6 to manufacture a wiring circuit board 23d. Note that a conductive paste may be printed to form the protrusion.

Next, a resist is applied onto the wiring layer forming metal layer 20c, followed by exposure and development to thereby form a resist mask (not shown). For example, a positive resist is applied, and an exposure mask with a predetermined pattern is used to expose the resist according to the mask pattern. In this embodiment, the resist located between the adjacent bumps 6 is exposed. Thereafter, the exposed resist is removed through the development so as to leave the resist mask (not shown) only underneath each bump 6. As shown in FIG. 18E, the wiring layer forming metal layer 20c is etched by using the resist mask as a mask to thereby form the wiring layer 10. Each wiring layer 10 is connected to the bump 6 through the etching barrier layer 8. In this way, a wiring circuit board 2g is manufactured.

The aforementioned method requires no heat-pressing apparatus and thus enhances the productivity of the wiring circuit board. Also, the height of the bump 6 can approximate the thickness of the insulating film 4, which eliminates the need for the formation of the bump 6 higher than necessary. As a result, a distance between the adjacent bumps 6 can be shortened, making it possible to manufacture the highly integrated wiring circuit board.

According to this embodiment, it is unnecessary to polish the insulating film 4 for exposing the top face of the bump 6. Thus, no resin remains on the top face of the bump 6. Consequently, the subsequent process is more easily conducted. In addition, the insulating film 4 is wholly removed through etching and hence, the resist mask is unnecessary. Accordingly, the steps necessary for forming the resist mask can be omitted.

Note that in this embodiment, as shown in FIG. 18B, the insulating film 4 is formed to a level somewhat higher than the bump 6 and then removed through etching. However, the present invention is not limited to this; the insulating film 4 may be formed to a level somewhat lower than the bump 6. Referring to FIGS. 19A to 19E, a method therefor is described.

As shown in FIG. 19A, the bump-equipped board 21 is prepared. Next, as shown in FIG. 19B, one surface of the board on which the bump 6 is formed is coated with a liquid insulating material in a precursor form by a curtain coater method, a doctor blade method, a bar coater method, or a screen printing method, for example. At this point, the insulating material is applied to a level somewhat lower than the bump 6. As shown in FIG. 19B, the liquid resin is cured and contracted and a volatile component volatizes, so that the insulating material remains on the top face of the bump 6 in a slight amount. The liquid insulating material is solidified by baking to form the insulating film 4. FIG. 19B shows the insulating film 4 thus formed by baking.

Next, as shown in FIG. 19C, the insulating film 4 is removed to such an extent as to completely expose at least the top face of each bump 6. A wiring circuit board 22e is thus manufactured. At this time, the insulating film 4 located between the bumps 6 is slightly etched and made thinner than that before etching. Here, the top face of the bump 6 has only to be completely exposed. After the top face is exposed, the insulating film 4 may be continuously and additionally etched.

Next, as shown in FIG. 19D, the protrusion 13 made of metal is formed on the top face of each bump 6 by plating to manufacture a wiring circuit board 23e. As shown in FIG. 19E, the wiring layer forming metal layer 20c is etched and patterned to thereby form the wiring layer 10. A wiring circuit board 2h is thus manufactured.

Note that in this embodiment as well, similar to the eighth embodiment, as the insulating material, the thermoplastic resin such as the liquid crystal polymer or PET may be used in addition to the polyimide resin. Here, the wiring layer 10 is formed after the protrusion 13 is formed. However, the wiring layer 10 may be formed before the protrusion 13 is formed.

In the eighth to tenth embodiments, the insulating material is removed by polishing or etching. However, the present invention is not limited thereto but may adopt laser processing to remove the material. As regards the laser processing, a carbon dioxide gas laser, an excimer laser, a YAG laser, a semiconductor laser, or the like is used only the insulating film 4 located on the bump 6 is irradiated with the laser beam and removed to such an extent as to completely expose the top face of the bump 6. By applying the laser beam only to the insulating film 4 located on the bump 6 in this way, the insulating film 4 on the bump 6 can be removed solely. Accordingly, this method obviates the need to form the resist mask and involves no residual resin on the board. The number of subsequent steps can be thus reduced. The thickness of the insulating film 4 may be either larger or smaller than the height of the bump 6.

The insulating resin on the bump 6 can be thinned by using a roll. This facilitates the removal of the residual resin in the subsequent steps. Assume that a board is passed through two rolls arranged at a given distance, for instance. In this case, the distance between the rolls is set somewhat smaller than the thickness of the board. The insulating material on the bump 6 is leveled by passing the board between the two rolls.

The insulating material remains on the top face of the bump 6 in a slight amount when the insulating material is leveled by means of the rolls. The insulating film 4 is wholly removed by etching to such an extent as to completely expose at least the top face of each bump 6. The wiring circuit board is thus manufactured. At this point, the thickness of the insulating film 4 substantially equals the height of the bump 6. Note that the top face of the bump 6 has only to be completely exposed. After the top face is exposed, the insulating film 4 may be continuously and additionally etched. In such a case, the thickness of the insulating film 4 is smaller than the height of the bump 6. An alkali solution or a hydrazine solution is used for etching, for example. The insulating film 4 may be removed through plasma ashing, UV ashing, or the like as well. Alternatively, the insulating film 4 may be removed through polishing or laser processing. Note that the thickness of the insulating film 4 may be either larger or smaller than the height of the bump 6.

In addition, the wiring circuit board can be manufactured using other methods. The top face of the bump 6 formed on the bump-equipped board 21 may be subjected to treatment for imparting a property of repelling the liquid insulating material. For example, a silicone resin or fluorine compound film is formed merely on the top face of the bump 6 by a stamp method, a roll coating method, or the like.

Here, the stamp method is a method of pressing a stamp attached with a silicone resin etc. against only the top face of the bump 6 and letting the silicone resin etc. adhere to the top face of the bump 6 alone. The roll coating method is a method of rotating a roll attached with a silicone resin etc. in contact with the top face of the bump 6 and letting the silicone resin etc. adhere to the top face of the bump 6.

Then, one surface of the board on which the bump 6 is formed is coated with a liquid insulating material including a polyimide resin, an epoxy resin, or the like in a precursor form by a curtain coater method, a doctor blade method, a bar coater method, or a screen printing method, for example. At this point, the insulating material is applied to a level somewhat lower than the bump 6. The silicone resin adheres to the top face of the bump 6 while repelling the liquid insulating material, with the result that no insulating material remains on the top face of the bump 6.

Then, the liquid insulating material is solidified by baking to form the insulating film 4. Thereafter, the top face of the bump 6 is polished to remove the silicone resin or the like. Alternatively, such a material may be removed by using a solvent capable of dissolving the silicone resin etc., or can be removed by using any physical technique such as plasma ashing or UV ashing.

The insulating film 4 can be also removed by sand blasting. For example, fine powder of glass, alumina, steel, silica sand, magnetite, carborundum, or the like is used as an abrasive (referred to as a blasting material) and injected toward the surface of the insulating film 4 in a highly accelerated state, together with high-pressure water and compressed air, for example. The surface of the insulating film 4 is polished through the utilization of impact to such an extent as to completely expose the top face of the bump 6.

(Eleventh Embodiment)

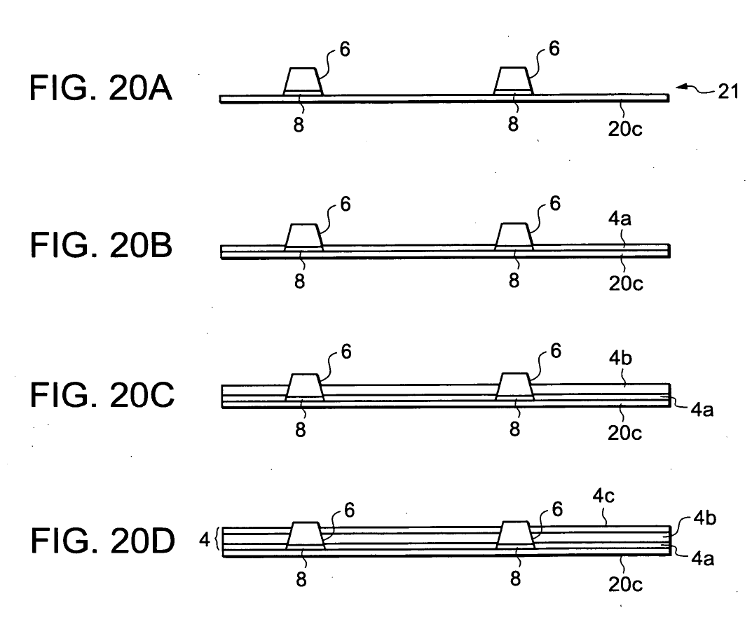

Referring next to FIGS. 20A to 20D, a manufacturing method for a wiring circuit board according to an eleventh embodiment of the present invention is described. In the eighth to tenth embodiments, the polyimide resin is used as the insulating material to form the single-layer insulating film 4. However, the present invention is not limited thereto. The insulating film 4 of two layers or three or more layers may be formed. Referring to FIGS. 20A to 20D, description is given of a structure of the insulating film 4 and a method of forming the same. FIGS. 20A to 20D are sectional views of the board, each of which illustrates the method of forming the multilayer insulating film 4.

As shown in FIG. 20A, the bump-equipped board 21 is prepared. As shown in FIG. 20B, one surface of the board on which the bump 6 is formed is coated with the insulating material including thermoplastic polyimide dissolved in a solvent or heat-melt polyimide dissolved as well in a solvent and heated at about 100 to 200° C. An insulating film 4a is thus formed. At this point, the insulating film 4a is formed to a level somewhat lower than the bump 6.

As shown in FIG. 20C, the insulating film 4a is coated with the insulating material including a polyimide resin in a precursor form by a curtain coater method, a doctor blade method, a bar coater method, or a screen printing method, for example. The insulating material is heated at about 350 to 400° C. to thereby form an insulating film 4b. Here, upon forming the insulating film, the total thickness of the insulating films 4a and 4b is made smaller than the height of the bump 6.

As shown in FIG. 20D, the insulating film 4b is coated with the insulating material including thermoplastic polyimide dissolved in a solvent and heated at about 100 to 200° C. An insulating film 4c is thus formed. The thickness of the completed insulating film 4 may be either larger or smaller than the height of the bump 6. The insulating film 4 is removed through polishing, etching, or laser processing to such an extent as to expose at least the top face of the bump 6. After that, the wiring layer 10 or the like is formed.

The formation of the insulating film 4 with such a structure produces the following effects. That is, the thermoplastic resin may substitute for an adhesive to the wiring layer. Thus, the insulating material including the thermoplastic resin constitutes a topmost layer of the wiring circuit board, making it easy to laminate the board to another wiring circuit board, a wiring layer forming metal layer, or the like. Further, an adhesion with another wiring circuit board etc. is improved.

Also, the insulating film 4a made of thermoplastic polyimide forms a lowermost layer of the insulating film 4 in contact with the wiring layer forming metal layer 20c, which improves the adhesion between the insulating film 4 and the wiring layer forming metal layer 20c.

Further, a polyamic acid is used as a precursor of the polyimide resin. The polyamic acid reacts with a copper foil used for the wiring layer forming metal layer 20c when in use. As a result, the adhesion between the insulating film 4 and the wiring layer forming metal layer 20c drops and the insulating film 4 peels off from the layer in some cases (occurrence of peeling-off). However, the insulating material including the thermoplastic resin is interposed therebetween to improve the adhesion between the insulating film 4 and the wiring layer forming metal layer 20c. Therefore, it is possible to prevent the occurrence of peeling-off.

In the above eighth to eleventh embodiments, the manufacturing method for the wiring circuit board using the liquid insulating material has been described so far. In the following embodiments, a multilayer wiring circuit board using the wiring circuit board and a manufacturing method for the multilayer wiring circuit board are described.

(Twelfth Embodiment)

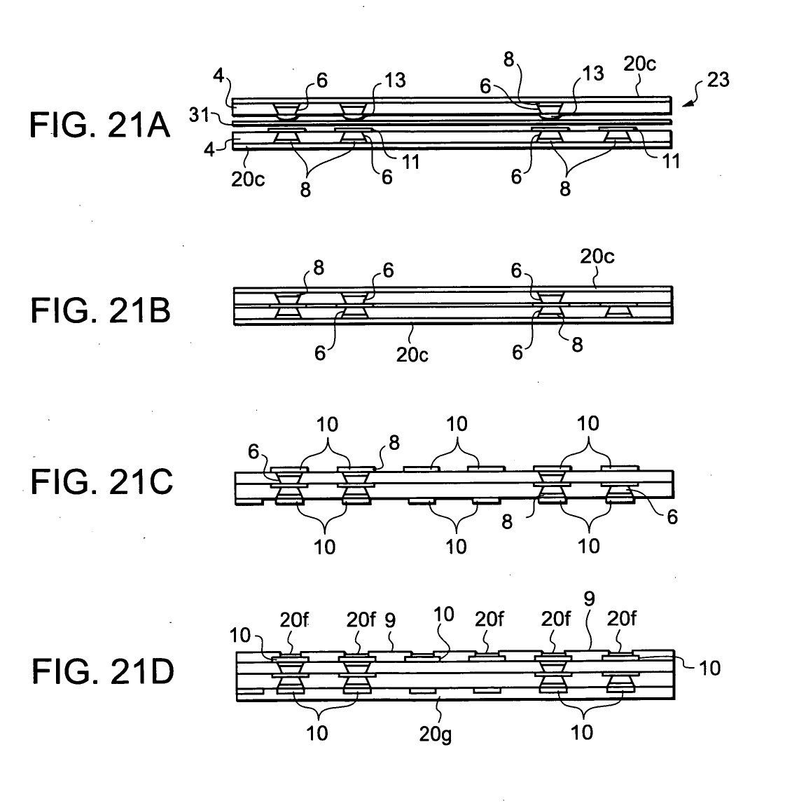

Referring next to FIGS. 21A to 21D, description is given of a manufacturing process for a multilayer wiring circuit board according to a twelfth embodiment of the present invention using the wiring circuit board manufactured by the manufacturing method according to the eighth to eleventh embodiments. FIGS. 21A to 21D are sectional views of the multilayer wiring circuit board according to the twelfth embodiment of the present invention, each of which illustrates a manufacturing method for the multilayer wiring circuit board in the manufacturing step order.

First, as shown in FIG. 21A, a bonding sheet 31, the wiring circuit board 23, and another wiring circuit board are prepared. The bonding sheet 31 is used for bonding the wiring circuit board 23 and the other wiring circuit board and is made of thermoplastic polyimide or a modified epoxy resin, for example.

Here, the wiring circuit board 23 is manufactured by the manufacturing method for the wiring circuit board according to the eighth embodiment. Regarding the other wiring circuit board, the bump 6 is formed on the wiring layer forming metal layer 20c through the etching barrier layer 20b and the wiring layer 11 is formed on the bump 6. The insulating film 4 is formed between the adjacent bumps 6 with the surface thereof flush with the top face of the bump 6.

The other wiring circuit board is manufactured as follows. That is, the wiring layer forming metal layer (not shown) is press-bonded to the surface of the wiring circuit board 22, on which the top face of the bump 6 is exposed. After that, the wiring layer forming metal layer is partially etched to form the wiring layer 11. For example, a positive resist is applied onto the wiring layer forming metal layer, and an exposure mask with a predetermined pattern is used to expose the resist located between the adjacent bumps 6. Thereafter, the resist located between the adjacent bumps 6 is removed through the development, so that a resist mask (not shown) is formed only on the top face of each bump 6. The wiring layer 11 is formed by etching the wiring layer forming metal layer using the resist mask as a mask.

Next, as shown in FIG. 21B, the wiring circuit board 23 and the other wiring circuit board next press-bonded under heating through the bonding sheet 31 to thereby manufacture the multilayer wiring circuit board. At this point, the wiring circuit boards are press-bonded to each other such that the protrusion 13 of the wiring circuit board 23 comes into contact with the wiring layer 11 of the other wiring circuit board.

Next, a resist is applied onto both of upper and lower surfaces of the multilayer wiring circuit board, followed by exposure and development to thereby form a resist mask (not shown). For example, a positive resist is applied, and an exposure mask with a predetermined pattern is used to expose the resist according to the mask pattern. Then, the exposed resist is removed through the development to reshape the resist mask (not shown). As shown in FIG. 21C, the wiring layer forming metal layers 20c on both surfaces of the board are etched by using the resist mask as a mask to thereby form the wiring layers 10 on both surfaces thereof. Each wiring layer 10 is connected to the bump 6 through the etching barrier layer 8. In this way, the bump is connected to the wiring layer and hence the bump functions as an interlayer connection means.

Next, as shown in FIG. 21D, a solder resist is applied onto one surface for protecting the surface where the wiring layer 10 is formed and for preventing the solder from adhering thereon. A resist mask 9 is formed through the exposure and development. Then, for example, a gold-flash-plated metal 20f is deposited on the wiring layer 10 formed on the surface concerned by plating. Also, the other surface of the board is coated with a cover lay film 20g. The cover lay film 20g is a polyimide film one surface of which is coated with an adhesive. Needless to say, the solder resist may be applied thereto instead of the cover lay film 20g.

As mentioned above, the wiring circuit boards with the distance between the bumps minimized are laminated, making it possible to manufacture the highly integrated multilayer wiring circuit board.

In this embodiment, the multilayer wiring circuit board is manufactured by utilizing the wiring circuit board 23 manufactured according to the manufacturing method of the eighth embodiment. However, the present invention is not limited thereto. For example, the multilayer wiring circuit board may be manufactured by utilizing the wiring circuit board 23a, the wiring circuit board 23b, or other such boards.

In this embodiment, the multilayer wiring circuit board is manufactured by using the bonding sheet 31 and the wiring circuit board 23 with the metal protrusion 13 formed thereon. However, the multilayer wiring circuit board can be manufactured without using those. For example, if the wiring circuit board 22a of the eighth embodiment is used, the multilayer wiring circuit board can be manufactured without using the bonding sheet 31. The wiring circuit board 22a has the bump 6 the height of which is larger than the thickness of the insulating film 4 such that the top face of the bump 6 protrudes from the insulating film 4. Accordingly, even if the metal protrusion 13 is not additionally formed by plating, using the uncured insulating resin or thermoplastic resin enables the top face of the bump 6 to directly contact and press-bond to the wiring layer 11 of another wiring circuit board without interposing the bonding sheet 31 therebetween. The multilayer wiring circuit board can be thus manufactured.

(Thirteenth Embodiment)

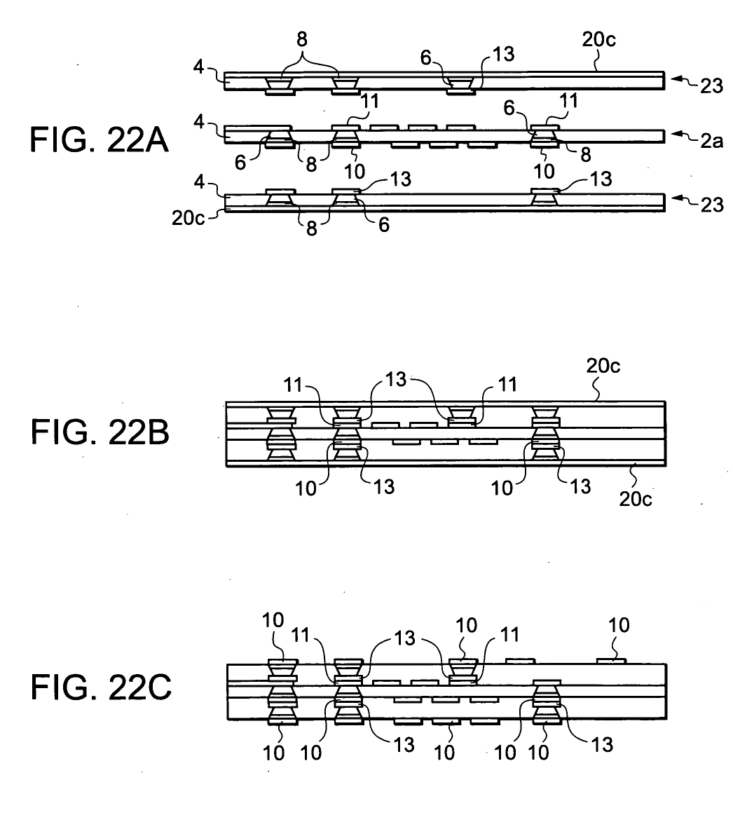

Referring next to FIGS. 22A to 22C, description is given of a manufacturing process for a multilayer wiring circuit board according to a thirteenth embodiment of the present invention using the wiring circuit board manufactured by the manufacturing method according to the eighth to eleventh embodiments. FIGS. 22A to 22C are sectional views of the multilayer wiring circuit board according to the thirteenth embodiment of the present invention, each of which illustrates a manufacturing method for the multilayer wiring circuit board in the manufacturing step order.

First, as shown in FIG. 22A, the two wiring circuit boards 23 and the wiring circuit board 2a are prepared. The wiring circuit board 2a is manufactured by the manufacturing method for the wiring circuit board according to the first embodiment. Each wiring circuit board 23 is manufactured by the manufacturing method for the wiring circuit board according to the eighth embodiment.

The wiring circuit board 2a is manufactured as follows. That is, the wiring layer forming metal layer is press-bonded to the surface of the wiring circuit board 22, on which the top face of the bump 6 is exposed. After that, the wiring layer forming metal layers on both of upper and lower surfaces are partially etched to form the wiring layer 10 and the wiring layer 11. For example, a positive resist is applied onto the wiring layer forming metal layer, and an exposure mask with a predetermined pattern is used to expose the resist according to the mask pattern. Thereafter, the exposed resist is removed through the development, so that a resist mask (not shown) is formed. The wiring layer 10 and the wiring layer 11 are formed by etching the wiring layer forming metal layers using the resist mask as a mask.

Next, as shown in FIG. 22B, the wiring circuit boards 23 are press-bonded to both surfaces of the wiring circuit board 2a under heating to thereby manufacture the multilayer wiring circuit board. At this point, the wiring circuit board 2a and the two wiring circuit boards 23 are press-bonded such that the protrusion 13 of one of the wiring circuit boards 23 comes into contact with the wiring layer 10 of the wiring circuit board 2a and the protrusion 13 of the other thereof comes into contact with the wiring layer 11 of the wiring circuit board 2a.

Next, a resist is applied onto both of upper and lower surfaces of the multilayer wiring circuit board, followed by exposure and development to thereby form a resist mask (not shown). For example, a positive resist is applied, and an exposure mask with a predetermined pattern is used to expose the resist according to the mask pattern. Thereafter, the exposed resist is removed through the development to reshape the resist mask. As shown in FIG. 22C, the wiring layer forming metal layers 23c formed on both of the upper and lower surfaces of the multilayer wiring circuit board are etched by using the resist mask as a mask to thereby form the wiring layers 10 on both surfaces thereof. Each wiring layer 10 is connected to the bump 6 through the etching barrier layer 8. In this way, the bump is connected to the wiring layer, and hence the bump functions as an interlayer connection means.

As mentioned above, the wiring circuit boards with the distance between the bumps minimized are laminated, making it possible to manufacture the highly integrated multilayer wiring circuit board.

In this embodiment, the multilayer wiring circuit board is manufactured by utilizing the wiring circuit board 23 manufactured according to the manufacturing method of the eighth embodiment. However, the present invention is not limited thereto. For example, the multilayer wiring circuit board may be manufactured by utilizing the wiring circuit board 23a, the wiring circuit board 23b, or other such boards.

In this embodiment, the multilayer wiring circuit board is manufactured using the wiring circuit boards 23 with the protrusion 13 formed thereon. However, the multilayer wiring circuit board can be manufactured without using the above. For example, the wiring circuit board 22a of the eighth embodiment may be used. The wiring circuit board 22a has the bump 6 the height of which is larger than the thickness of the insulating film 4 such that the top face of the bump 6 protrudes from the insulating film 4. Accordingly, even if the metal protrusion 13 is not formed, the multilayer wiring circuit board can be manufactured by causing the top face of the bump 6 to directly contact and press-bond to the wiring layer 10 and the wiring layer 11 of the wiring circuit board 2a.

(Fourteenth Embodiment)

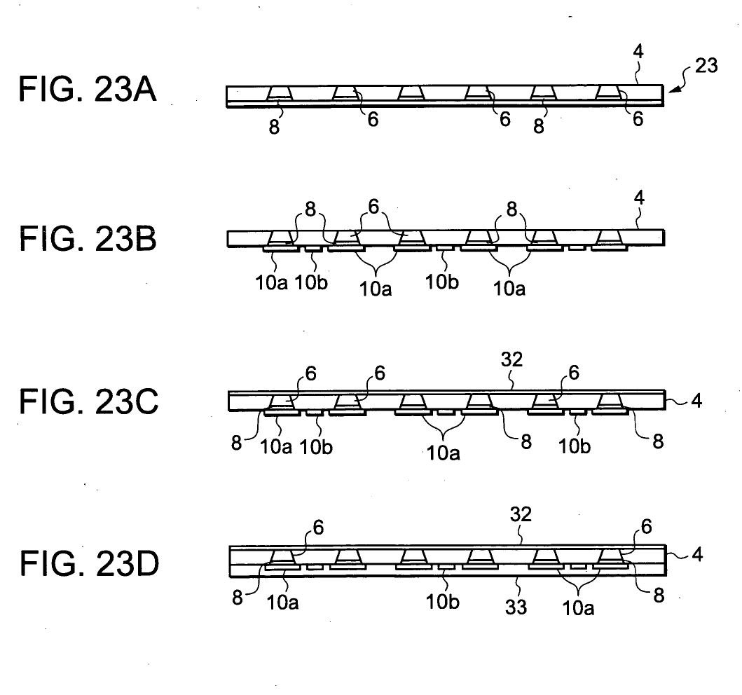

Referring next to FIGS. 23A to 23D, description is given of a manufacturing process for another wiring circuit board according to a fourteenth embodiment of the present invention using the wiring circuit board manufactured by the manufacturing method according to the eighth to eleventh embodiments. FIGS. 23A to 23D are sectional views of the wiring circuit board according to the fourteenth embodiment of the present invention, each of which illustrates a manufacturing method for the wiring circuit board in the manufacturing step order.

First, as shown in FIG. 23A, the wiring circuit board 22 is prepared. Then, a resist is applied onto the wiring layer forming metal layer 20c, followed by exposure and development to thereby form a resist mask (not shown). For example, a positive resist is applied, and an exposure mask with a predetermined pattern is used to expose the resist according to the mask pattern. Thereafter, the exposed resist is removed through development to reshape the resist mask (not shown). As shown in FIG. 23B, the wiring layer forming metal layer 20c is etched by using the resist mask as a mask to thereby form a wiring layer 10a and a wiring layer 10b. The wiring layer 10a and the wiring layer 10b are alternately formed. Also, the wiring layer 10a is connected to the bump 6 through the etching barrier layer 8.

Next, as shown in FIG. 23C, one surface of the board on which the bump 6 is exposed is attached with an electromagnetic shielding sheet 32 made of a copper foil, an aluminum foil, an iron foil, an SUS foil, or the like, and an adhesive. The electromagnetic shielding sheet 32 functions to shield an electromagnetic wave generated from the wiring circuit board as well as to prevent any malfunction due to the undesirable electromagnetic wave from the outside. In this embodiment, the electromagnetic shielding sheet 32 is attached to the entire board surface. However, the sheet may be partially attached thereto in contact with the top face of the bump 6. As shown in FIG. 23D, a resist 33 is applied onto the surface where the wiring layer 10a and the wiring layer lob are formed to thereby manufacture the wiring circuit board with the electromagnetic shield.

In this embodiment, the wiring layer 10a is connected to the electromagnetic shielding sheet 32 through the bump 6 and thus functions as a ground line. Meanwhile, the wiring layer 10b functions as a signal line. The wiring layer 10a and the wiring layer 10b are alternately formed, enabling a reduction in cross-talk generated between the adjacent wiring layers 10b. The highly integrated wiring circuit board with the electromagnetic shield can be manufactured by making use of the wiring circuit board with the distance between the bumps minimized.

Further, the electromagnetic shielding sheets may be attached to both surfaces of the wiring circuit board. Such a structure produces an effect in that the wiring layer can be used as a microstrip line for an RF line as well. In this embodiment, the ground line is disposed for each signal line (each wiring layer lob). However, it is not always necessary to arrange the ground lines and the signal lines in a one-to-one correspondence.

Note that in this embodiment, the wiring circuit board with the electromagnetic shield is manufactured by making use of the wiring circuit board 22 manufactured by the manufacturing method of the eighth embodiment. However, the present invention is not limited thereto. The electromagnetic shielding layer (sheet) can be formed by a method of applying a conductive paste or a printing method as well. Also, the wiring circuit board with the electromagnetic shield may be manufactured by making use of the wiring circuit board 22a etc. manufactured by the manufacturing method of the eighth embodiment.

(Fifteenth Embodiment)

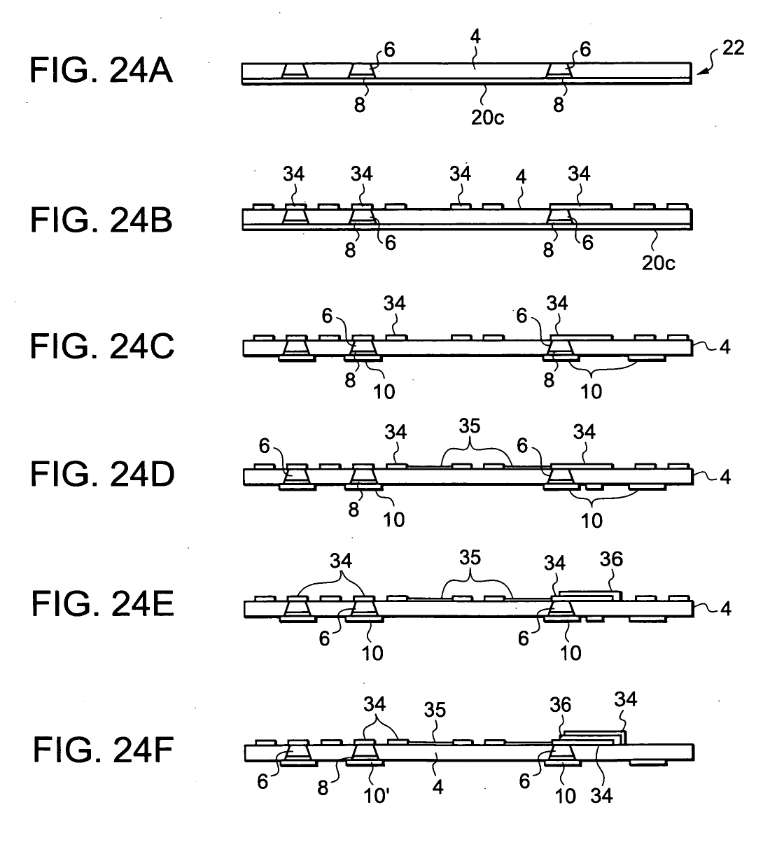

Referring next to FIGS. 24A to 24F, description is given of a manufacturing process for another wiring circuit board according to a fifteenth embodiment of the present invention using the wiring circuit board manufactured by the manufacturing method according to the eighth to eleventh embodiments. FIGS. 24A to 24F are sectional views of the wiring circuit board according to the fifteenth embodiment of the present invention, each of which illustrates a manufacturing method for the wiring circuit board in the manufacturing step order.

As shown in FIG. 24A, the wiring circuit board 22 is prepared. As shown in FIG. 24B, a conductive paste 34 made of metal such as gold, silver, or copper is partially applied onto the surface of the board on which the top face of the bump 6 is exposed by an ink-jet method, a screen printing method, a dispenser method, or the like. A part of the conductive paste 34 is in contact with the top face of the bump 6.

Next, a resist is applied onto the wiring layer forming metal layer 20c, followed by exposure and development to thereby form a resist mask (not shown). For example, a positive resist is applied onto the wiring layer forming metal layer 20c, and an exposure mask with a predetermined pattern is used to expose the resist according to the mask pattern. Thereafter, the exposed resist is removed through the development to reshape the resist mask (not shown). As shown in FIG. 24C, the wiring layer forming metal layer 20c is etched by using the resist mask as a mask to thereby form the wiring layer 10. The wiring layer 10 is connected to the bump 6 through the etching barrier layer 8.

Next, as shown in FIG. 24D, a resistor paste 35 is applied between the adjacent conductive pastes 34 by the inkjet method, the screen printing method, the dispenser method, or the like. As shown in FIG. 24E, a dielectric paste 36 is then applied onto the conductive paste 34 in contact with the top face of the bump 6 by the inkjet method, the screen printing method, the dispenser method, or the like. Then, as shown in FIG. 24F, the additional conductive paste 34 is applied onto the dielectric paste 36. The dielectric paste 36 is thus sandwiched between the conductive pastes 34 to form a capacitor element.

As mentioned above, a polymer type thick-film circuit is composed on one surface of the wiring circuit board by applying or forming the resistor paste or the capacitor element thereon. At the same time, a wiring film made of copper is formed on the other surface of the board, by which a circuit can be composed. The height of the bump 6 can approximate the thickness of the insulating film 4, which eliminates the need for the formation of the bump 6 higher than necessary. Also, the wiring circuit board with the distance between the bumps minimized is utilized, making it possible to manufacture the wiring circuit board where a signal circuit of a very weak current and a circuit requiring a high current of a power source etc. are highly integrated.

Note that in this embodiment, the wiring layer 10 is formed after the conductive paste 34 is formed. However, the present invention is not limited thereto. The wiring layer 10 may be formed before the conductive paste 34 is formed. Alternatively, the wiring layer 10 may be formed through etching after the capacitor element is formed.

In this embodiment, the capacitor element is formed by applying the conductive paste, the resistor paste, and the dielectric paste by the inkjet method, the screen printing method, or the dispenser method. However, the present invention is not limited thereto. For example, a conductive material, a resistor material, and a dielectric material are deposited into a film on one surface of the wiring circuit board by a sputtering method, a CVD method, or an evaporation method. Then, patterning is effected through etching and thus, the conductive film, the resistor film, and the dielectric film may be formed. The sputtering method enables thin film formation, making it possible to compose a thin-film circuit on the polymer film.

Note that as the conductive material, metal such as Cu, Au, Ag, Al, Ni, Ti, Cr, NiCr, Nb, or V is used. As the resistor material, NiCr, Ta₂N, RuO₂, SnO, or the like is used. As the dielectric material, SrTiO₃, BaTiO₃, TiO, or the like is used.

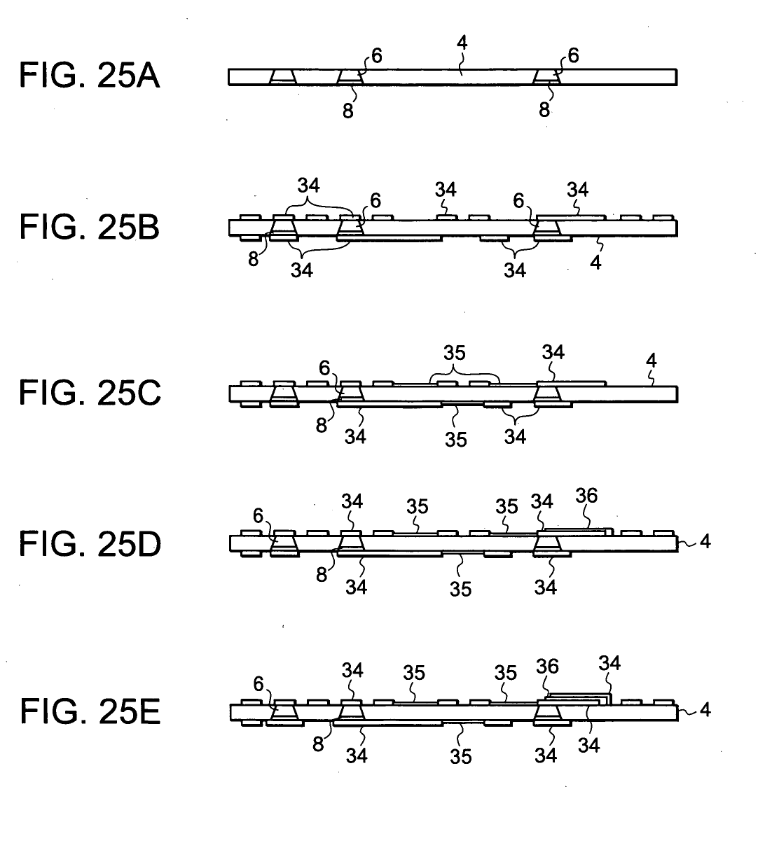

Also in this embodiment, the thick- or thin-film circuit is composed on one surface of the wiring circuit board. It is also possible to form the thick- or thin-film circuits on both surfaces thereof. Referring to FIGS. 25A to 25E, a method therefor is described. FIGS. 25A to 25E are sectional views of the wiring circuit board, each of which illustrates a manufacturing method for the wiring circuit board in the manufacturing step order.

As shown in FIG. 25A, the wiring circuit board having the bump 6 penetrating through the insulating film 4 is prepared. The wiring circuit board is manufactured by wholly removing, through etching, the wiring layer forming metal layer 20c formed on the wiring circuit board 22. Next, as shown in FIG. 25B, the conductive paste 34 made of gold, silver, copper, or the like is partially applied onto both of the upper and lower surfaces of the wiring circuit board by the inkjet method, the screen printing method, the dispenser method, or the like.

Next, as shown in FIG. 25C, the resistor paste 35 is applied between the adjacent conductive pastes 34 by the inkjet method or the like. As shown in FIG. 25D, the dielectric paste 36 is then applied onto the conductive paste 34 in contact with the top face of the bump 6 by the inkjet method or the like. Then, as shown in FIG. 25E, the additional conductive paste 34 is applied onto the dielectric paste 36. The dielectric paste 36 is thus sandwiched between the conductive pastes 34 to form a capacitor element.

As described above, the thick-film circuit can be composed by applying or forming the resistor paste or the capacitor element on both surfaces of the wiring circuit board. The height of the bump 6 can approximate the thickness of the insulating film 4, which eliminates the need for the formation of the bump 6 higher than necessary. Also, the wiring circuit board with the distance between the bumps minimized is utilized, making it possible to manufacture the wiring circuit board where the signal circuit is highly integrated. Note that the conductive material etc. may be deposited into a film by the sputtering method instead of using the inkjet method. The sputtering method enables the thin film formation, making it possible to compose a finer thin-film circuit.

Note that in this embodiment, the wiring circuit board is manufactured by making use of the wiring circuit board 22 manufactured by the manufacturing method of the eighth embodiment. However, the present invention is not limited thereto. The wiring circuit board may be manufactured by making use of the wiring circuit board 22a etc. manufactured by the manufacturing method of the eighth embodiment.

(Sixteenth Embodiment)

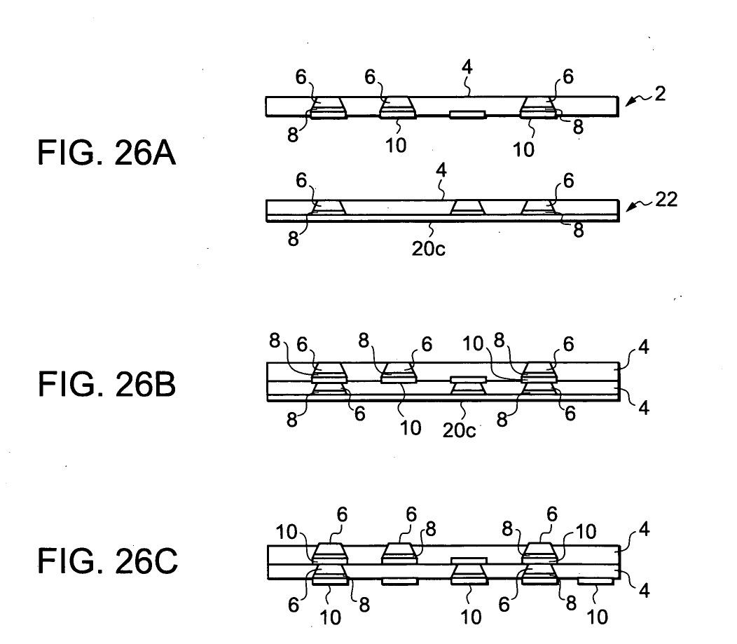

Referring next to FIGS. 26A to 26C, description is given of a manufacturing process for a multilayer wiring circuit board according to a sixteenth embodiment of the present invention using the wiring circuit board manufactured by the manufacturing method according to the eighth to eleventh embodiments. FIGS. 26A to 26C are sectional views of the multilayer wiring circuit board according to the sixteenth embodiment of the present invention, each of which illustrates a manufacturing method for the multilayer wiring circuit board in the manufacturing step order.

As shown in FIG. 26A, the wiring circuit board 2 and the wiring circuit board 22 are prepared. The wiring circuit board 2 is manufactured by the manufacturing method according to the first embodiment. The wiring circuit board 22 is manufactured by the manufacturing method according to the eighth embodiment.

Next, as shown in FIG. 26B, the wiring circuit board 2 and the wiring circuit board 22 are press-bonded to each other such that the top face of the bump 6 of the wiring circuit board 22 comes into contact with the wiring layer 10 of the wiring circuit board 2 to thereby manufacture the multilayer wiring circuit board. In this way, the bump 6 is connected to the wiring layer 10 and hence, the bump 6 functions as an interlayer connection means.

As shown in FIG. 26C, the wiring layer 10 is formed by partially etching the wiring layer forming metal layer 20c of the multilayer wiring circuit board. The wiring layer 10 is connected to the bump 6 through the etching barrier layer 8.

As discussed above, the wiring circuit boards with the distance between the bumps minimized are laminated, making it possible to manufacture the highly integrated multilayer wiring circuit board. Also the multilayer wiring circuit board of this embodiment has the bump 6 the top face of which protrudes from the insulating film 4. Thus, components (elements) can be directly and firmly mounted to the top face as compared with the soldering or the like. In addition, no component (element) is mounted at a position on the pattern. Therefore, there is no fear that the pattern is peeled off to allow the component (element) to come off. Also, the insulating film 4 surrounds the bump 6 and produces the same effect as when the hard solder resist is formed.

Note that in this embodiment, the multilayer wiring circuit board is manufactured by making use of the wiring circuit board 22 manufactured by the manufacturing method of the eighth embodiment. However, the present invention is not limited thereto. The multilayer wiring circuit board may be manufactured by making use of the wiring circuit board 22a etc. manufactured by the manufacturing method of the eighth embodiment.

(Seventeenth Embodiment)

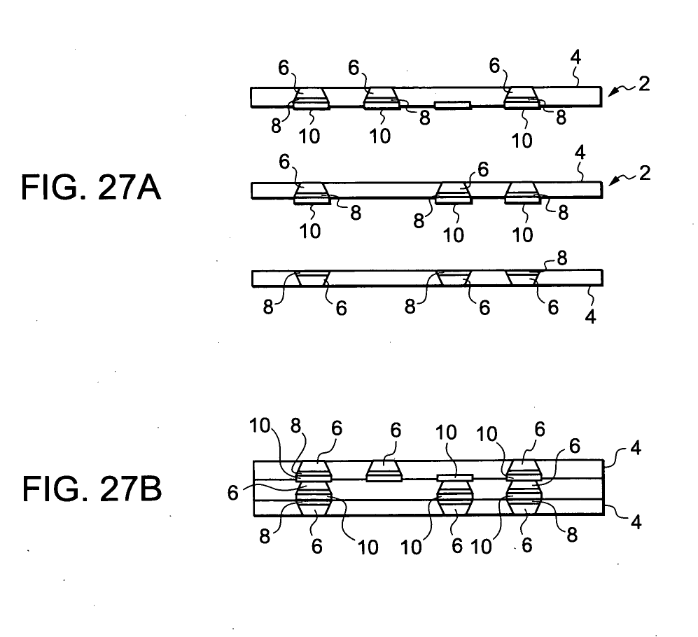

Referring next to FIGS. 27A and 27B, description is given of a manufacturing process for a multilayer wiring circuit board according to a seventeenth embodiment of the present invention using the wiring circuit board manufactured by the manufacturing method according to the eighth to eleventh embodiments. FIGS. 27A and 27B are sectional views of the multilayer wiring circuit board according to the seventeenth embodiment of the present invention, each of which illustrates a manufacturing method for the multilayer wiring circuit board in the manufacturing step order.

As shown in FIG. 27A, the two wiring circuit boards 2 and another wiring circuit board having the bump 6 penetrating through the insulating film 4 are prepared. The wiring circuit boards 2 are each manufactured by the manufacturing method for the wiring circuit board according to the first embodiment. For that matter, the boards are each manufactured by partially etching the wiring layer forming metal layer 20c of the wiring circuit board 22 manufactured by the manufacturing method of the eighth embodiment to form the wiring layer 10. Meanwhile, the other wiring circuit board is manufactured by completely removing, through etching, the wiring layer forming metal layer 20c formed on the wiring circuit board 22.

Next, as shown in FIG. 27B, the two wiring circuit boards 2 are press-bonded to each other such that the top face of the bump 6 of one of the wiring circuit boards 2 comes into contact with the wiring layer 10 of the other thereof. Further, the wiring circuit board 2 is press-bonded to the other wiring circuit board such that the wiring layer 10 of the wiring circuit board 2 comes into contact with the bottom face of the bump 6 of the other wiring circuit board. In this way, the bump is connected to the wiring layer and hence, the bump functions as an interlayer connection means.

As discussed above, the wiring circuit boards with the distance between the bumps minimized are laminated, making it possible to manufacture the highly integrated multilayer wiring circuit board. Also the multilayer wiring circuit board of this embodiment has the bump 6 the top face of which protrudes from the insulating film 4. Thus, the components (elements) can be directly mounted to the top face. In addition, no component (element) is mounted through plating. Therefore, there is no fear that plating is peeled off to allow the component (element) to come off. Also, the insulating film 4 surrounds the bump 6 and produces the same effect as when the solder resist is formed.

Note that in this embodiment, the multilayer wiring circuit board is manufactured by making use of the wiring circuit board 22 manufactured by the manufacturing method of the eighth embodiment. However, the present invention is not limited thereto. The multilayer wiring circuit board may be manufactured by making use of the wiring circuit board 22a etc. manufactured by the manufacturing method of the eighth embodiment.

(Eighteenth Embodiment)

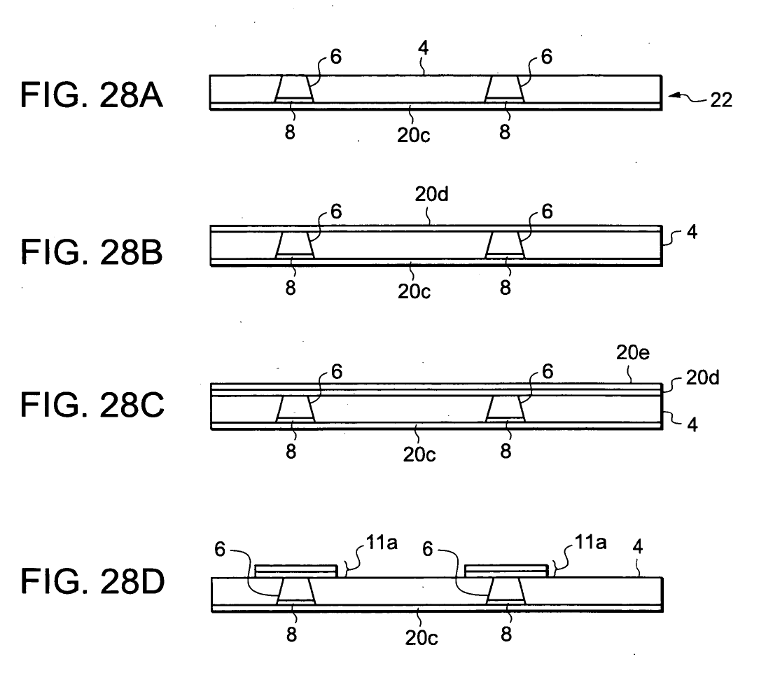

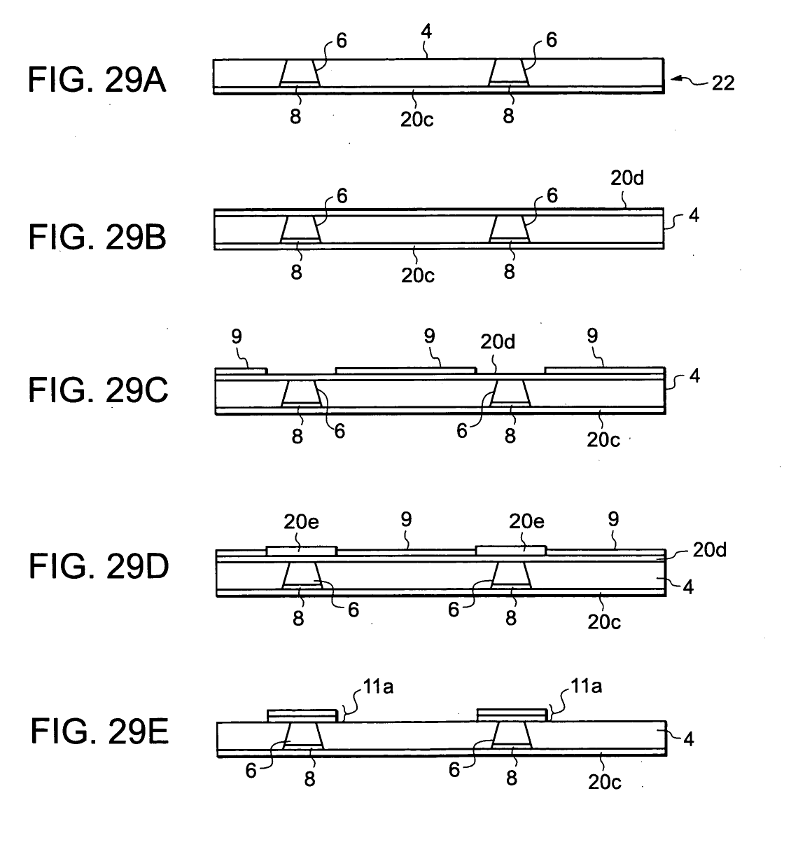

Referring next to FIGS. 28A to 28D and FIGS. 29A to 29E, description is given of a manufacturing process for another wiring circuit board according to an eighteenth embodiment of the present invention using the wiring circuit board manufactured by the manufacturing method according to the eighth to eleventh embodiments. FIGS. 28A to 28D and FIGS. 29A to 29E are sectional views of the wiring circuit board according to the eighteenth embodiment of the present invention, each of which illustrates a manufacturing method for the wiring circuit board in the manufacturing step order.

As shown in FIG. 28A, the wiring circuit board 22 is prepared. The wiring circuit board 22 is manufactured by the manufacturing method according to the eighth embodiment. Next, as shown in FIG. 28B, a thin film 20d is formed on the surface where the top face of the bump 6 is exposed at the surface of the insulating film 4 by electroless plating.

Next, as shown in FIG. 28C, a metal film 20e made of copper is formed on the thin film 20d by electrolytic plating. A resist is applied onto the metal film 20e, followed by exposure and development to thereby form a resist mask (not shown). For example, a positive resist is applied, and an exposure mask with a predetermined pattern is used to expose the resist according to the mask pattern. In this embodiment, the resist located between the adjacent bumps 6 is exposed. Thereafter, the exposed resist is removed through the development so as to leave the resist mask (not shown) only on the top face of each bump 6.

Next, as shown in FIG. 28D, the thin film 20d and the metal film 20e are etched by using the resist mask as a mask to form a wiring layer 11a with the predetermined pattern. The wiring circuit board is thus manufactured.

In this embodiment, the thin film is formed by electroless plating and the wiring layer 11a is formed by electrolytic plating to thereby manufacture the wiring circuit board. However, the wiring circuit board can be manufactured by another method as explained hereinafter with reference to FIGS. 29A to 29E.

As shown in FIG. 29A, the wiring circuit board 22 is prepared. Next, as shown in FIG. 29B, the thin film 20d made of copper is formed on the surface where the top face of the bump 6 is exposed at the surface of the insulating film 4 by electroless plating.

Next, as shown in FIG. 29C, a resist is applied onto the thin film 20d, followed by exposure and development to thereby form the resist mask 9 between the bumps 6. For example, a positive resist is applied, and an exposure mask with a predetermined pattern is used to expose the resist according to the mask pattern. In this embodiment, the resist applied onto the top face of the bump 6 is exposed. Thereafter, the exposed resist is removed through the development so as to leave the resist mask 9 between the bumps 6. By forming the resist mask 9 in such a manner, the resist mask 9 is not formed on each bump 6.

Next, as shown in FIG. 29D, copper as a material for the metal film 20e is allowed to precipitate on the surface of the thin film 20d by chemical plating. At this time, copper precipitates only in a portion where the resist is removed but does not precipitate in a portion where the resist mask 9 is formed. After that, the resist mask 9 is removed and the entire surface is etched. Thus, the thin film 20d formed between the metal films 20e is removed to form the wiring layer 11a. During the etching, the surface of the wiring layer 11a is somewhat etched; however, the thickness of the wiring layer 11a is larger than that of the thin film 20d and hence, the wiring layer 11a is by no means removed even if the thin film 20d is completely removed.

Note that in this embodiment, the thin film 20d is formed by electroless plating but may be formed by a sputtering method instead. Also, in this embodiment, the other wiring circuit board is manufactured by making use of the wiring circuit board 22 manufactured by the manufacturing method according to the eighth embodiment. However, the present invention is not limited thereto. The other wiring circuit board may be manufactured by making use of the wiring circuit board 22a etc. manufactured by the manufacturing method of the eighth embodiment.

(Nineteenth Embodiment)

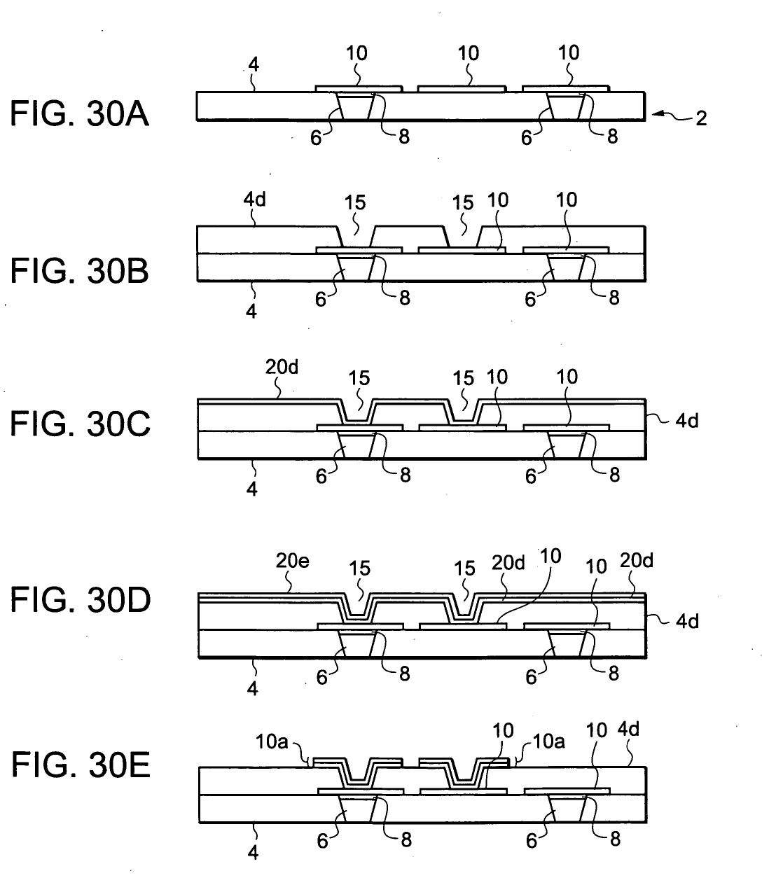

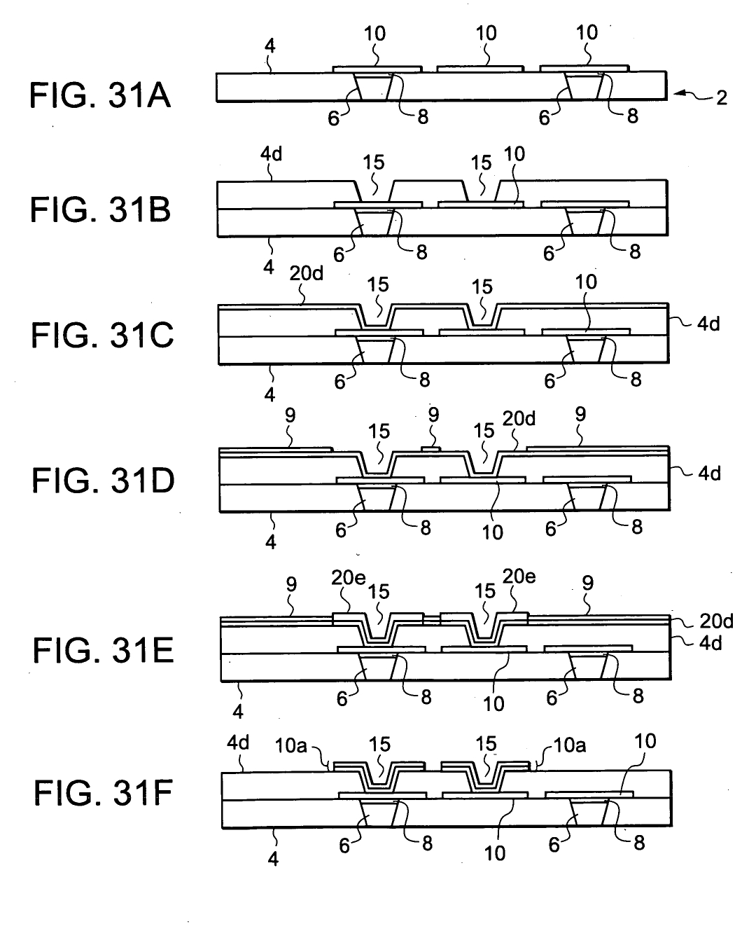

Referring next to FIGS. 30A to 30E and FIGS. 31A to 31F, description is given of a manufacturing process for a multilayer wiring circuit board according to a nineteenth embodiment of the present invention using the wiring circuit board manufactured by the manufacturing method according to the eighth to eleventh embodiments. FIGS. 30A to 30E and FIGS. 31A to 31F are sectional views of the multilayer wiring circuit board according to the nineteenth embodiment of the present invention, each of which illustrates a manufacturing method for the multilayer wiring circuit board in the manufacturing step order.

As shown in FIG. 30A, the wiring circuit board 2 is prepared. Next, an insulating film 4d is laminated on the surface where the wiring layer 10 is formed. As shown in FIG. 30B, the insulating film 4d is perforated to form a through-hole 15. The through-hole 15 can be formed, for example, by applying a laser beam to part of the insulating film 4d. The through-hole 15 may be formed in the insulating film 4d by partially etching the film, apart from the laser irradiation.

Next, as shown in FIG. 30C, the thin film 20d made of copper is formed on the insulating film 4d by electroless plating. The thin film 20d is also formed inside the through-hole 15 in contact with the wiring layer 10. Next, as shown in FIG. 30D, the metal film 20e is formed on the thin film 20d by electrolytic plating.

A resist is applied onto the metal film 20e, followed by exposure and development to form a resist mask (not shown) on an inner wall of the through-hole 15 and its vicinities. For example, a positive resist is applied, and an exposure mask with a predetermined pattern is used to expose the resist according to the mask pattern. In this embodiment, the resist applied onto a portion other than the through-hole 15 is exposed. Thereafter, the exposed resist is removed through the development so as to reshape the resist mask (not shown) on the inner wall of the through-hole 15 and its vicinities.

Next, as shown in FIG. 30E, the thin film 20d and the metal film 20e are etched by using the resist mask as a mask to form the wiring layer 10a with a predetermined pattern.

In this embodiment, the thin film 20d is formed by electroless plating and the wiring layer 10a is formed by electrolytic plating to thereby manufacture the multilayer wiring circuit board. However, the multilayer wiring circuit board can be manufactured by another method as explained hereinafter with reference to FIGS. 31A to 31F.

As shown in FIG. 31A, the wiring circuit board 2 is prepared. Next, the insulating film 4d is laminated on the surface where the wiring layer 10 is formed. As shown in FIG. 31B, the insulating film 4d is perforated to form the through-hole 15. Next, as shown in FIG. 31C, the thin film 20d made of copper is formed on the insulating film 4d by electroless plating. The thin film 20d is also formed inside the through-hole 15 in contact with the wiring layer 10.

Next, as shown in FIG. 31D, a resist is applied onto the thin film 20d, followed by exposure and development to form the resist mask 9 on a portion other than the through-hole 15. For example, a positive resist is applied, and an exposure mask with a predetermined pattern is used to expose the resist according to the mask pattern. In this embodiment, the resist applied onto the inside of the through-hole 15 and its vicinities is exposed. Thereafter, the resist applied onto the inside of the through-hole 15 and its vicinities is removed through the development.

Next, as shown in FIG. 31E, copper as a material for the metal film 20e is allowed to precipitate on the surface of the thin film 20d by chemical plating. At this time, copper precipitates only in a portion where the resist is removed but does not precipitate in a portion where the resist mask 9 is formed. After that, the resist mask 9 is removed and the thin film 20d formed in a portion other than the through-hole 15 is removed through etching. As shown in FIG. 31F, the wiring layer 10a is thus formed. During the etching, the surface of the wiring layer 10a is somewhat etched as well; however, the thickness of the wiring layer 10a is larger than that of the thin film 20d and hence, the wiring layer 10a is by no means removed even if the thin film 20d is completely removed.

Note that in this embodiment, the thin film 20d is formed by electroless plating but may be formed by the sputtering method instead. Also, in this embodiment, the multilayer wiring circuit board is manufactured by making use of the wiring circuit board 22 manufactured by the manufacturing method according to the eighth embodiment. However, the present invention is not limited thereto. The multilayer wiring circuit board may be manufactured by making use of the wiring circuit board 22a etc. manufactured by the manufacturing method of the eighth embodiment.

(Twentieth Embodiment)

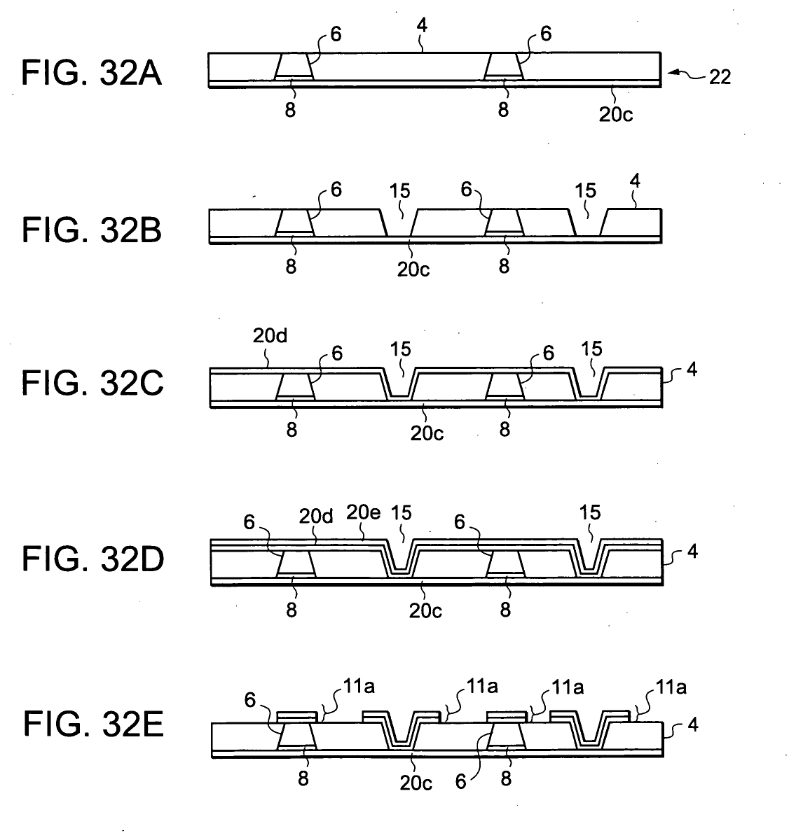

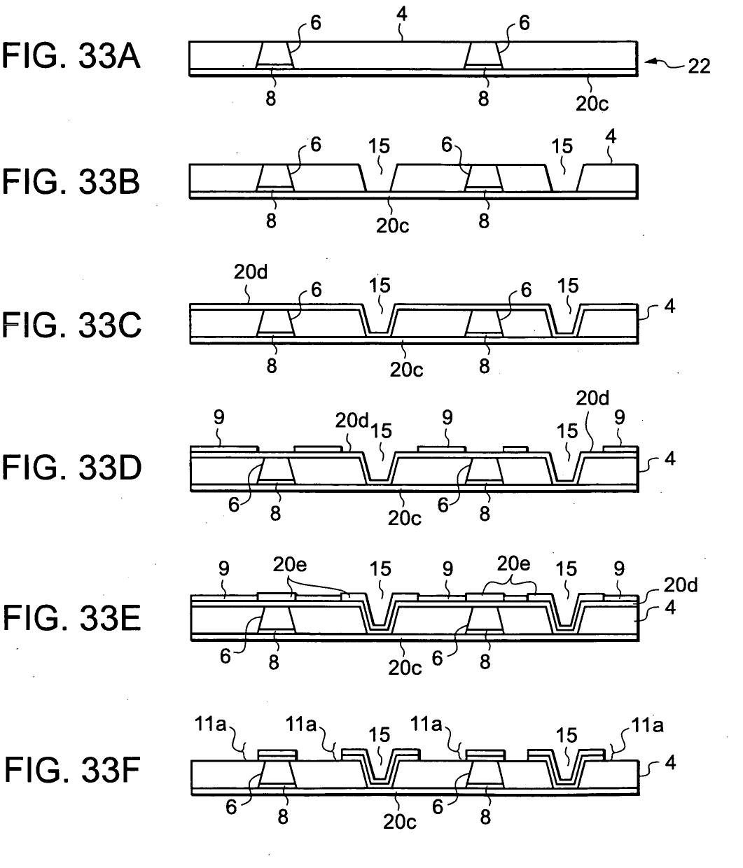

Referring next to FIGS. 32A to 32E and FIGS. 33A to 33F, description is given of a manufacturing process for another wiring circuit board according to a twentieth embodiment of the present invention using the wiring circuit board manufactured by the manufacturing method according to the eighth to eleventh embodiments. FIGS. 32A to 32E and FIGS. 33A to 33F are sectional views of the wiring circuit board according to the twentieth embodiment of the present invention, each of which illustrates a manufacturing method for the wiring circuit board in the manufacturing step order.

As shown in FIG. 32A, the wiring circuit board 22 is prepared. The wiring circuit board 22 is manufactured by the manufacturing method according to the eighth embodiment. Next, as shown in FIG. 32B, the insulating film 4 is perforated to form the through-hole 15. The through-hole 15 can be formed, for example, by applying a laser beam to part of the insulating film 4. The through-hole may be formed in the insulating film 4 by partially etching the film, apart from the laser irradiation.

Next, as shown in FIG. 32C, the thin film 20d made of copper is formed on the insulating film 4 by electroless plating. The thin film 20d is also formed inside the through-hole 15 in contact with the wiring layer forming metal layer 20c. Next, as shown in FIG. 32D, the metal film 20e made of copper is formed on the thin film 20d by electrolytic plating.

Next, a resist is applied onto the metal film 20e, followed by exposure and development to form a resist mask (not shown) on an inner wall of the through-hole 15 and the bump 6. For example, a positive resist is applied, and an exposure mask with a predetermined pattern is used to expose the resist according to the mask pattern. In this embodiment, the resist applied onto a portion other than the inner wall of the through-hole 15 and a portion above the bump 6 is exposed. Thereafter, the exposed resist is removed through the development so as to reshape the resist mask (not shown) on the inner wall of the through-hole 15 and the bump 6. As shown in FIG. 32E, the thin film 20d and the metal film 20e are etched by using the resist mask as a mask to form the wiring layer 11a with the predetermined pattern.

In this embodiment, the thin film 20d is formed by electroless plating and the wiring layer 11a is formed by electrolytic plating to thereby manufacture the wiring circuit board. However, the wiring circuit board can be manufactured by another method as explained hereinafter with reference to FIGS. 33A to 33F.

As shown in FIG. 33A, the wiring circuit board 22 is prepared. Next, as shown in FIG. 33B, the insulating film 4 is perforated to form the through-hole 15. Next, as shown in FIG. 33C, the thin film 20d made of copper is formed on the insulating film 4 by electroless plating. The thin film 20d is also formed inside the through-hole 15 in contact with the wiring layer forming metal layer 20c.

Next, as shown in FIG. 33D, a resist is applied onto the thin film 20d, followed by exposure and development to form the resist mask 9 on a portion other than the inside of the through-hole 15 and a portion above the bump 6. For example, a positive resist is applied, and an exposure mask with a predetermined pattern is used to expose the resist according to the mask pattern. In this embodiment, the resist applied onto the inside of the through-hole 15 and the portion above the bump 6 is exposed. Thereafter, the resist applied onto the inside of the through-hole 15 and the portion above the bump 6 is removed through the development.

Next, as shown in FIG. 33E, copper as a material for the metal film 20e is allowed to precipitate on the surface of the thin film 20d by chemical plating. At this time, copper precipitates only in a portion where the resist is removed but does not precipitate in a portion where the resist mask 9 is formed. After that, the resist mask 9 is removed and the thin film 20d formed in a portion other than the inside of the through-hole 15 and the portion above the bump 6 is removed through etching. As shown in FIG. 33F, the wiring layer 11a is thus formed. During the etching, the surface of the wiring layer 11a is somewhat etched as well; however, the thickness of the wiring layer 11a is larger than that of the thin film 20d and hence, the wiring layer 11a is by no means removed even if the thin film 20d is completely removed.

Note that in this embodiment, the thin film 20d is formed by electroless plating but may be formed by the sputtering method instead. Also, in this embodiment, the other wiring circuit board is manufactured by making use of the wiring circuit board 22 manufactured by the manufacturing method according to the eighth embodiment. However, the present invention is not limited thereto. The other wiring circuit board may be manufactured by making use of the wiring circuit board 22a etc. manufactured by the manufacturing method of the eighth embodiment.

The present invention is applicable to the wiring circuit board for packaging an electronic device such as an IC or an LSI, in particular, the wiring circuit board capable of high-density packaging, the manufacturing method for the same, and the circuit module having the wiring circuit board. A specific example of the circuit module is a liquid crystal display; however, the present invention is not limited thereto but is applicable to another module.

1 A wiring circuit board comprising:
a plurality of bumps each formed on a surface of a wiring layer directly or indirectly through an etching barrier layer;
an insulating film formed on the surface of the wiring layer on which the bumps are formed at a portion in which the bumps are not formed; and
a solder ball formed on a top face of each of the bumps directly or indirectly through an additional wiring layer.

2 A wiring circuit board according to claim 1, wherein the wiring layer, an additional wiring layer, and the bumps are made of copper.

3 A wiring circuit board according to claim 1 or 2, wherein:
the insulating film has a bump formation region where the plurality of bumps are formed and a flexible bump non-formation region where the bumps are not formed; and
the bump non-formation region can be bent or at least a part of the bump non-formation region is bent.

4 A wiring circuit board according to claim 1 or 2, wherein:
the top face of each of the bumps is formed in a rounded concave shape; and
the solder ball is directly formed on the top face of each of the bumps.

5 A circuit module comprising:
a flexible wiring circuit board including:
a plurality of bumps each formed on a surface of a wiring layer directly or indirectly through an etching barrier layer;
an insulating film formed on the surface of the wiring layer on which the bumps are formed at a portion in which the bumps are not formed; and
a solder ball formed on a top face of each of the bumps directly or indirectly through an additional wiring layer; and
a rigid wiring circuit board having a rigid insulated board where a wiring layer is formed on at least one surface thereof, which is connected to the wiring layer,
wherein at least a part of the wiring layer of the flexible wiring circuit board and at least a part of the wiring layer of the rigid wiring circuit board are connected to each other through the solder ball.

6 A circuit module comprising:
a flexible wiring circuit board including:
a plurality of bumps each formed on a surface of a wiring layer directly or indirectly through an etching barrier layer;
an insulating film formed on the surface of the wiring layer on which the bumps are formed at a portion in which the bumps are not formed; and
a solder ball formed on a top face of each of the bumps directly or indirectly through an additional wiring layer; and
an additional flexible wiring circuit board having a flexible insulated board having at least one surface on which a wiring layer connected to the wiring layer is formed,
wherein at least a part of the wiring layer of the flexible wiring circuit board and at least a part of the wiring layer of the additional flexible wiring circuit board are connected to each other through the solder ball.

7 A circuit module according to claim 5 or 6, wherein:
the top face of each of the bumps is formed in a rounded concave shape; and
the solder ball is directly formed on the top face of each of the bumps.

8 A manufacturing method for a wiring circuit board comprising:
forming a board in which a bump is formed on a surface of a metal layer directly or indirectly through an etching barrier layer;
forming an insulating film on the surface of the metal layer on which the bump is formed at a portion in which the bump is not formed while making the insulating film thicker than the bump;
polishing the insulating film to an extent to which a top face of the bump is exposed; and
forming a solder ball on the top face of the bump.

9 A manufacturing method for a wiring circuit board comprising:
forming a board in which a bump is formed on a surface of a metal layer directly or indirectly through an etching barrier layer;
forming an insulating film on the surface of the metal layer on which the bump is formed at a portion in which the bump is not formed while making the insulating film thicker than the bump;
polishing the insulating film of the board to an extent to which a top face of the bump is exposed;
forming an additional metal layer on a surface of the insulating film of the board;
selectively etching the additional metal layer to form a wiring layer; and
forming a solder ball on the top face of the bump directly or indirectly through the wiring layer connected to the bump.

10 A manufacturing method for a wiring circuit board according to claim 8 or 9, further comprising, before forming the insulating film, pressurizing the bump from above and flattening out the bump to increase a diameter of the top face of the bump.

11 A manufacturing method for a wiring circuit board according to claim 8 or 9, further comprising, after polishing the insulating film to an extent to which the top face of the bump is exposed and before forming the solder ball on the top face of the bump, etching the top face of the bump into a rounded concave shape.

12 A circuit module comprising:
a single wiring circuit board including:
a plurality of bumps each formed on a surface of a wiring layer directly or indirectly through an etching barrier layer; and
an insulating film formed on the surface of the wiring layer on which the bumps are formed at a portion in which the bumps are not formed; and
a transparent board for a liquid crystal device which constitutes a board for the liquid crystal device and includes a transparent wiring film,
wherein each of the bumps of the single wiring circuit board and a portion corresponding to the bump, of the transparent wiring film of the transparent board for the liquid crystal device are connected to each other directly or indirectly through the wiring layer formed on the top face of the bump and a solder ball thereon.

13 A circuit module according to claim 12, wherein:
the top face of each of the bumps of the signal wiring circuit board is formed in a rounded concave shape; and
the solder ball is directly formed on the top face of each of the bumps.

14 A manufacturing method for a wiring circuit board, comprising:
forming a board in which a bump is formed on a surface of a metal layer directly or indirectly through an etching barrier layer,
forming an insulating film by applying a liquid insulating material on the surface of the metal layer on which the bump is formed and solidifying the insulating material through heat treatment; and
removing the insulating film to an extent to which a top face of the bump is exposed.

15 A manufacturing method for a wiring circuit board using a multilayer metal plate in which a bump forming metal layer is formed on a wiring layer forming metal layer directly or indirectly through an etching barrier layer, comprising:
forming a bump by applying a resist onto the bump forming metal layer and forming a resist mask through patterning, and etching the bump forming metal layer by using the resist mask as a mask;
removing the etching barrier layer through etching by using the bump as a mask after removing the resist mask;
forming an insulating film by applying a liquid insulating material on the surface of the metal layer on which the bump is formed and solidifying the insulating material through heat treatment; and
removing the insulating film to an extent to which a top face of the bump is exposed.

16 A manufacturing method for a wiring circuit board according to claim 14 or 15, wherein the insulating material is made of a precursor of a polyimide resin or an epoxy resin.

17 A manufacturing method for a wiring circuit board according to claim 14 or 15, wherein in forming the insulating film, an insulating material including a melted thermoplastic resin is applied on the surface of the board on which the bump is formed and solidified under cooling to form the insulating film.

18 A manufacturing method for a wiring circuit board according to claim 14 or 15, wherein in forming the insulating film, the liquid insulating material is applied onto the surface of the board on which the bump is formed, left standing to dry and solidify, leveled by a roll, and cured through heat treatment to form the insulating film.

19 A manufacturing method for a wiring circuit board according to claim 14 or 15, wherein in forming the insulating film, a thermoplastic polyimide resin is applied onto the surface of the board on which the bump is formed and dried and solidified under heating, applied with a non-thermoplastic polyimide resin in a precursor form, and dried and solidified under heating to form the insulating film.

20 A manufacturing method for a wiring circuit board according to claim 14 or 15, wherein in removing the insulating film, the insulating film is mechanically polished to an extent to which at least the top face of the bump is exposed.

21 A manufacturing method for a wiring circuit board according to claim 14 or 15, wherein in removing the insulating film, a resist is applied onto the insulating film and the resist on the bump is removed through exposure and development, and the insulating film formed on the bump is removed through etching by using as a mask the resist applied onto a portion where the bump is not formed to an extent to which at least the top face of the bump is exposed.

22 A manufacturing method for a wiring circuit board according to claim 14 or 15, wherein in removing the insulating film, the insulating film is wholly etched and removed to an extent to which at least the top face of the bump is exposed.

23 A manufacturing method for a wiring circuit board according to claim 14 or 15, wherein in removing the insulating film, the insulating film formed on the bump is removed by laser processing to an extent to which at least the top face of the bump is exposed.

24 A manufacturing method for a wiring circuit board according to claim 14 or 15, wherein in removing the insulating film, the insulating film is removed by injecting a gas containing an abrasive onto the surface of the insulating film to an extent to which at least the top face of the bump is exposed.

25 A manufacturing method for a wiring circuit board according to claim 14 or 15, wherein in removing the insulating film, the insulating film is removed by injecting a liquid containing an abrasive onto the surface of the insulating film to an extent to which at least the top face of the bump is exposed.

26 A manufacturing method for a wiring circuit board according to claim 14 or 15, wherein in forming the insulating film, the insulating film is formed with a thickness larger than a height of the bump.

27 A manufacturing method for a wiring circuit board according to claim 14 or 15, wherein in forming the insulating film, the insulating film is formed with a thickness smaller than a height of the bump.

28 A manufacturing method for a wiring circuit board using a board having a wiring layer forming metal layer and a bump formed on the wiring layer forming metal layer directly or indirectly through an etching barrier layer, comprising:
applying a material repelling a liquid resin onto a top face of the bump;
applying a liquid insulating material thereonto; and
solidifying the insulating material through heat treatment to thereby form an insulating film.

29 A manufacturing method for a wiring circuit board according to claim 14 or 15, further comprising, after removing the insulating film, forming a protrusion made of metal on the top face of the bump by plating.

30 A manufacturing method for a wiring circuit board according to claim 29, further comprising, after forming the protrusion by plating, forming a wiring layer by partially etching the wiring layer forming metal layer.

31 A manufacturing method for a wiring circuit board according to claim 14 or 15, further comprising, after removing the insulating film, forming a wiring layer by partially etching the wiring layer forming metal layer.

32 A manufacturing method for a wiring circuit board according to claim 31, further comprising, after forming the wiring layer, forming a protrusion made of metal on the top face of the bump by plating.

33 A manufacturing method for a wiring circuit board according to claim 14 or 15, further comprising, after removing the insulating film:
laminating an additional wiring layer forming metal layer on the insulating film; and
forming a wiring layer by partially etching the additional wiring layer forming metal layer.

34 A manufacturing method for a wiring circuit board according to claim 14 or 15, further comprising, after removing the insulating film, wholly removing the wiring layer forming metal layer through etching.

35 A manufacturing method for a wiring circuit board according to claim 14 or 15, further comprising, after removing the insulating film:
partially forming a first metal film on the insulating film;
forming a resistor film on the insulating film at a portion where the first metal film is not formed;
forming a dielectric film on the first metal film;
forming a second metal film on the dielectric film; and
forming a wiring layer by partially etching the wiring layer forming metal layer formed on the wiring circuit board.

36 A manufacturing method for a wiring circuit board according to claim 35, wherein the first metal film and the second metal film are made of a conductive paste, the resistor film is made of a resistor paste, and the dielectric film is made of a dielectric paste.

37 A manufacturing method for a wiring circuit board according to claim 35, wherein the first metal film, the second metal film, the resistor film, and the dielectric film are formed by one selected from the group consisting of a sputtering method, a CVD method, and an evaporation method.

38 A manufacturing method for a wiring circuit board according to claim 14 or 15, further comprising, after removing the insulating film:
forming a wiring layer by partially etching the wiring layer forming metal layer to connect a part of the wiring layer with the bump directly or indirectly through the etching barrier layer; and
forming an electromagnetic shielding sheet wholly or partially on a surface on which the top face of the bump is exposed.

39 A manufacturing method for a wiring circuit board using a wiring circuit board manufactured by the manufacturing method for the wiring circuit board according to claim 14 or 15, comprising:
forming a thin film made of metal on the insulating film and the top face of the bump by electroless plating or sputtering;
forming a metal film on the thin film by electrolytic plating; and
forming a wiring layer by applying a resist onto the metal film to form a resist pattern through patterning, and etching the metal film using the resist pattern as a mask.

40 A manufacturing method for a wiring circuit board using a wiring circuit board manufactured by the manufacturing method for the wiring circuit board according to claim 14 or 15, comprising:
forming a thin film made of metal on the insulating film and the top face of the bump by electroless plating or sputtering;
forming a resist pattern by applying a resist onto the thin film and performing patterning;
precipitating metal by plating onto the thin film on which the resist pattern is not formed; and
removing the thin film by removing the resist pattern and wholly etching the film.

41 A manufacturing method for a wiring circuit board using a wiring circuit board manufactured by the manufacturing method for the wiring circuit board according to claim 14 or 15, comprising:
forming a through-hole by removing a part of the insulating film on the wiring circuit board by laser processing or etching;
forming a thin film on the insulating film and the top face of the bump by electroless plating or sputtering;
forming a metal film on the thin film by electrolytic plating; and
forming a wiring film by applying a resist onto the metal film to form a resist pattern through patterning, and etching the metal film using the resist pattern as a mask.

42 A manufacturing method for a wiring circuit board using a wiring circuit board manufactured by the manufacturing method for the wiring circuit board according to claim 14 or 15, comprising:
forming a through-hole by removing a part of the insulating film on the wiring circuit board by laser processing or etching;
forming a thin film on the insulating film and the top face of the bump by electroless plating or sputtering;
forming a resist pattern by applying a resist onto the thin film and performing patterning;
precipitating metal by plating onto the thin film on which the resist pattern is not formed; and
removing the thin film by removing the resist pattern and wholly etching the film.

43 A manufacturing method for a multilayer wiring circuit board using a wiring circuit board manufactured by the manufacturing method for the wiring circuit board according to claim 33, comprising:
forming a multilayer metal plate by laminating a wiring circuit board manufactured by the manufacturing method for the wiring circuit board according to claim 29 claim 14, which has a protrusion formed on the top face of the bump directly or indirectly through a bonding sheet such that the protrusion comes into contact with the wiring layer; and
forming wiring layers on both of upper and lower surfaces of the multilayer metal plate by partially etching wiring layer forming metal layers formed on both of the upper and lower surfaces.

44 A manufacturing method for a multilayer wiring circuit board using a wiring circuit board manufactured by the manufacturing method for the wiring circuit board according to claim 33, comprising: forming a multilayer metal plate by laminating a wiring circuit board manufactured by the manufacturing method for the wiring circuit board according to claim 14, in which a bump is formed such that a top face of the bump comes into contact with the wiring layer directly or indirectly through a bonding sheet; and
forming wiring layers on both of upper and lower surfaces of the multilayer metal plate by partially etching wiring layer forming metal layers formed on both of the upper and lower surfaces.

45 A manufacturing method for a multilayer wiring circuit board using a wiring circuit board manufactured by the manufacturing method for the wiring circuit board according to claim 35, comprising, with respect to both of upper and lower surfaces thereof, on which wiring layers are formed:
forming a multilayer metal plate by laminating a wiring circuit board manufactured by the manufacturing method for the wiring circuit board according to claim 29 claim 14, which has a protrusion formed on a top face of a bump such that the protrusion comes into contact with the wiring layer; and
forming wiring layers on both of upper and lower surfaces of the multilayer metal plate by partially etching the wiring layer forming metal layers formed on both of the upper and lower surfaces.

46 A manufacturing method for a multilayer wiring circuit board using a wiring circuit board manufactured by the manufacturing method for the wiring circuit board according to claim 35, comprising, with respect to both of upper and lower surfaces thereof, on which wiring layers are formed:
forming a multilayer metal plate by laminating a wiring circuit board manufactured by the manufacturing method for the wiring circuit board according to claim 14, in which a bump is formed such that a top face of the bump comes into contact with the wiring layer; and
forming wiring layers on both of upper and lower surfaces of the multilayer metal plate by partially etching the wiring layer forming metal layers formed on both of the upper and lower surfaces.

47 A manufacturing method for a multilayer wiring circuit board, comprising laminating on a wiring circuit board manufactured by the manufacturing method for the wiring circuit board according to claim 31, in which a wiring layer is formed, an additional wiring circuit board manufactured by the manufacturing method for the wiring circuit board according to claim 14, in which a bump is formed such that a top face of the bump comes into contact with the wiring layer.

48 A manufacturing method for a multilayer wiring circuit board, comprising laminating on a wiring circuit board manufactured by the manufacturing method for the wiring circuit board according to claim 31, an additional wiring circuit board manufactured by the manufacturing method for the wiring circuit board according to claim 14, such that a top face of a bump of the additional wiring circuit board comes into contact with a wiring layer of the wiring circuit board.

49 A manufacturing method for a multilayer wiring circuit board, comprising laminating on a multilayer wiring circuit board manufactured by the manufacturing method for the multilayer wiring circuit board according to claim 48, a wiring circuit board manufactured by the manufacturing method for the wiring circuit board according to claim 14, in which a bump is formed such that a bottom face of the bump comes into contact with a wiring layer of the multilayer wiring circuit board.

50 A manufacturing method for a multilayer wiring circuit board using a wiring circuit board manufactured by the manufacturing method for the wiring circuit board according to claim 31, comprising;
forming an insulating film by applying a liquid insulating material onto a surface where the wiring layer is formed and solidifying the insulating material through heat treatment;
forming a through-hole by removing a part of the insulating film by laser processing or etching;
forming a thin film on the insulating film by electroless plating or sputtering;
forming a metal film on the thin film by electrolytic plating; and
forming a wiring film by applying a resist onto the metal film to form a resist pattern through patterning, and etching the metal film using the resist pattern as a mask.

51 A manufacturing method for a multilayer wiring circuit board using a wiring circuit board manufactured by the manufacturing method for the wiring circuit board according to claim 31, comprising;
forming an insulating film by applying a liquid insulating material onto a surface where the wiring layer is formed and solidifying the insulating material through heat treatment;
forming a through-hole by removing a part of the insulating film by laser processing or etching;
forming a thin film on the insulating film by electroless plating or sputtering;
forming a resist pattern by applying a resist onto the thin film and performing patterning;
precipitating metal by plating onto the thin film on which the resist pattern is not formed; and
removing the thin film by removing the resist pattern and wholly etching the film.
